(19) United States
(12) Patent Application Publication
(10) Pub. No.: US 2024/0145484 A1
(43) Pub. Date: May 2, 2024

(54) DISPLAY DEVICE

(71) Applicant: Japan Display Inc., Tokyo (JP)

(72) Inventor: Yoshitaka OZEKI, Tokyo (JP)

(21) Appl. No.: 18/379,876

(22) Filed: Oct. 13, 2023

(30) Foreign Application Priority Data
Oct. 26, 2022 (JP) 2022-171597

(51) Int. Cl. H01L 27/12; G02F 1/1362

(52) U.S. Cl. CPC H01L 27/1225; G02F 1/136209; H01L 27/124; H01L 27/1248

(57) ABSTRACT

A display device includes a plurality of pixels arranged in a matrix on a substrate along a first direction and a second direction intersecting the first direction, each of the plurality of pixels including a transistor, a first wiring arranged over the transistor and electrically connected to the transistor, a first transparent conductive layer arranged over the first wiring and electrically connected to the transistor, a first insulating layer arranged on the first transparent conductive layer, and having a contact hole, and a second transparent conductive layer arranged on the first insulating layer and electrically connected to the first transparent conductive layer via the contact hole.

### CROSS-REFERENCE TO RELATED APPLICATIONS

This application claims the benefit of priority to Japanese Patent Application No. 2022-171597, filed on Oct. 26, 2022, the entire contents of which are incorporated herein by reference.

### FIELD

An embodiment of the present invention relates to a display device. In particular, an embodiment of the present invention relates to a display device in which a transistor including an oxide semiconductor is used. In addition, an embodiment of the present invention relates to an array substrate of a display device.

### BACKGROUND

Recently, a transistor using an oxide semiconductor as a channel has been developed instead of amorphous silicon, low-temperature polysilicon, and single-crystal silicon (for example, Japanese laid-open patent publication No. 2014-146819 and Japanese laid-open patent publication No. 2015-159315). Similar to a transistor in which amorphous silicon is used as a channel, a transistor in which an oxide semiconductor is used as a channel is formed with a simple structure and a low-temperature process. The transistor using the oxide semiconductor as the channel is known to have higher mobility and very lower off-state current than the transistor using amorphous silicon as the channel.

For example, an IPS type liquid crystal display device is known as a display device (Japanese laid-open patent publication No. 2015-087600). A source electrode of a transistor is connected to a pixel electrode via an opening arranged in an organic passivation film and an interlayer insulating film.

### SUMMARY

A display device according to an embodiment of the present invention includes a plurality of pixels arranged in a matrix on a substrate along a first direction and a second direction intersecting the first direction, each of the plurality of pixels including a transistor, a first wiring arranged over the transistor and electrically connected to the transistor, a first transparent conductive layer arranged over the first wiring and electrically connected to the transistor, a first insulating layer arranged on the first transparent conductive layer, and having a contact hole, and a second transparent conductive layer arranged on the first insulating layer and electrically connected to the first transparent conductive layer via the contact hole, wherein the first insulating layer has a recess portion overlapping the first transparent conductive layer, the recess portion is continuous with the contact hole, and the contact hole is arranged at a bottom part of the recess portion.

A display device according to an embodiment of the present invention includes a plurality of pixels arranged in a matrix on a substrate along a first direction and a second direction intersecting the first direction, each of the plurality of pixels including a transistor, a first wiring arranged over the transistor and electrically connected to the transistor, a first transparent conductive layer arranged over the first wiring and electrically connected to the transistor, a first insulating layer arranged on the first transparent conductive layer, and having a contact hole, and a second transparent conductive layer arranged on the first insulating layer and electrically connected to the first transparent conductive layer via the contact hole, wherein the first insulating layer has a recess portion extending over a plurality of pixels arranged side-by-side in the second direction, the recess portion is arranged continuously with the contact hole, and the contact hole is arranged at a bottom part of the recess portion overlapping the first transparent conductive layer.

A display device according to an embodiment of the present invention includes a substrate, a pixel arranged on the substrate, and having a transistor, a pixel electrode, and a common electrode, a wiring connected to a first electrode of the transistor, a conductive layer connected to a second electrode of the transistor, an insulating layer arranged over the conductive layer, and having a contact hole, wherein the pixel electrode is connected to the conductive layer via the contact hole, the contact hole includes a first region having a first side surface and a second region having a second side surface located between the first region and the conductive layer, a bottom part of the first region is continuous with a top of the second region, a tangent line of the first side surface at a bottom of the first region makes a first angle with a main surface of the substrate, a tangent line of the second side surface at a bottom of the second region makes a second angle with the main surface of the substrate, the first angle is less than the second angle, and a portion of the insulating layer is located between the wiring and the common electrode.

### BRIEF DESCRIPTION OF DRAWINGS

FIG. 1 is a plan view showing an outline of a display device according to an embodiment of the present invention.

FIG. 2 is a diagram showing a configuration of a display device according to an embodiment of the present invention.

FIG. 3 is a circuit diagram showing a pixel circuit of a pixel of a display device according to an embodiment of the present invention.

FIG. 4 is a cross-sectional view showing a configuration of a display device according to an embodiment of the present invention.

FIG. 5 is a plan view showing a configuration of a display device according to an embodiment of the present invention.

FIG. 6 is a plan view showing a configuration of a display device according to an embodiment of the present invention.

FIG. 7 is a cross-sectional view at a line A1-A2 of a display device shown in FIG. 5 and FIG. 6.

FIG. 8A is a cross-sectional view at a line B1-B2 of a display device shown in FIG. 5 and FIG. 6.

FIG. 8B is a cross-sectional view at a line B1-B2 of a display device shown in FIG. 5 and FIG. 6.

FIG. 9 is a plan view illustrating layouts of each layer in a display device according to an embodiment of the present invention.

FIG. 10 is a plan view illustrating layouts of each layer in a display device according to an embodiment of the present invention.

FIG. 11 is a plan view illustrating layouts of each layer in a display device according to an embodiment of the present invention.

FIG. 12 is a plan view illustrating layouts of each layer in a display device according to an embodiment of the present invention.

FIG. 13 is a plan view illustrating layouts of each layer in a display device according to an embodiment of the present invention.

FIG. 14 is a plan view illustrating layouts of each layer in a display device according to an embodiment of the present invention.

FIG. 15 is a plan view illustrating layouts of each layer in a display device according to an embodiment of the present invention.

FIG. 16 is a plan view illustrating layouts of each layer in a display device according to an embodiment of the present invention.

FIG. 17 is a plan view illustrating layouts of each layer in a display device according to an embodiment of the present invention.

FIG. 18 is a plan view illustrating layouts of each layer in a display device according to an embodiment of the present invention.

FIG. 19 is a plan view illustrating layouts of each layer in a display device according to an embodiment of the present invention.

FIG. 20 is a plan view showing a configuration of a display device according to an embodiment of the present invention.

FIG. 21 is a cross-sectional view at a line C1-C2 of a display device shown in FIG. 20.

FIG. 22 is a cross-sectional view at a line E1-E2 of a display device shown in FIG. 20.

FIG. 23 is a cross-sectional view showing a method for manufacturing a display device according to an embodiment of the present invention.

FIG. 24 is a cross-sectional view showing a method for manufacturing a display device according to an embodiment of the present invention.

FIG. 25 is a cross-sectional view showing a method for manufacturing a display device according to an embodiment of the present invention.

FIG. 26 is a plan view showing a configuration of a display device according to an embodiment of the present invention.

FIG. 27 is a cross-sectional view at a line F1-F2 of a display device shown in FIG. 26.

FIG. 28 is a cross-sectional view at a line G1-G2 of a display device shown in FIG. 26.

FIG. 29 is a cross-sectional view at a line H1-H2 of a display device shown in FIG. 26.

FIG. 30 is a cross-sectional view of a display device of a comparative example.

FIG. 31 is a cross-sectional view of a display device of a comparative example.

### DESCRIPTION OF EMBODIMENTS

Hereinafter, embodiments of the present invention will be described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of the respective parts in comparison with the actual embodiments. However, the illustrated shapes are merely examples, and do not limit the interpretation of the present invention. In the present specification and the drawings, the same components as those described above with respect to the above-described drawings are denoted by the same reference signs, and a detailed description thereof may be omitted as appropriate.

In the embodiments of the present invention, a direction from a substrate toward an oxide semiconductor layer is referred to as upper or above. Conversely, a direction from an oxide semiconductor layer to a substrate is referred to as lower or below. In this way, for convenience of explanation, although the phrases “above” or “below” are used in the description, for example, the upper and lower relationship between the substrate and the oxide semiconductor layer may be arranged in a different direction from that shown in the drawings. In the following explanation, for example, the expression “oxide semiconductor layer on substrate” merely describes the upper and lower relationship between the substrate and the oxide semiconductor layer as described above, and another member may be arranged between the substrate and the oxide semiconductor layer. The phrases “above” or “below” means a stacking order of a structure in which a plurality of layers is stacked, and may be a positional relationship in which a transistor and a pixel electrode do not overlap in a plan view when expressed as a pixel electrode above the transistor. On the other hand, when expressed as a pixel electrode vertically above the transistor, it means the positional relationship in which the transistor and the pixel electrode overlap in a plan view.

A “display device” refers to a structure that displays an image using an electro-optic layer. For example, the term display device may refer to a display panel including the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer and an electrophoretic layer, unless there is a technical inconsistency. Therefore, although embodiments described later will be described by exemplifying a liquid crystal display device including a liquid crystal layer as a display device, the configuration in the present embodiment can be applied to a display device including the other electro-optic layers described above.

In this specification, the expression “α includes A, B, or C,” “α includes any of A, B, and C,” “α includes one selected from a group consisting of A, B, and C,” and the like does not exclude the case where α includes a plurality of combinations of A to C unless otherwise specified. Furthermore, these expressions do not exclude the case where α includes other elements.

In addition, the following embodiments can be combined with each other as long as there is no technical inconsistency.

### First Embodiment

### 1. Outline of Display Device

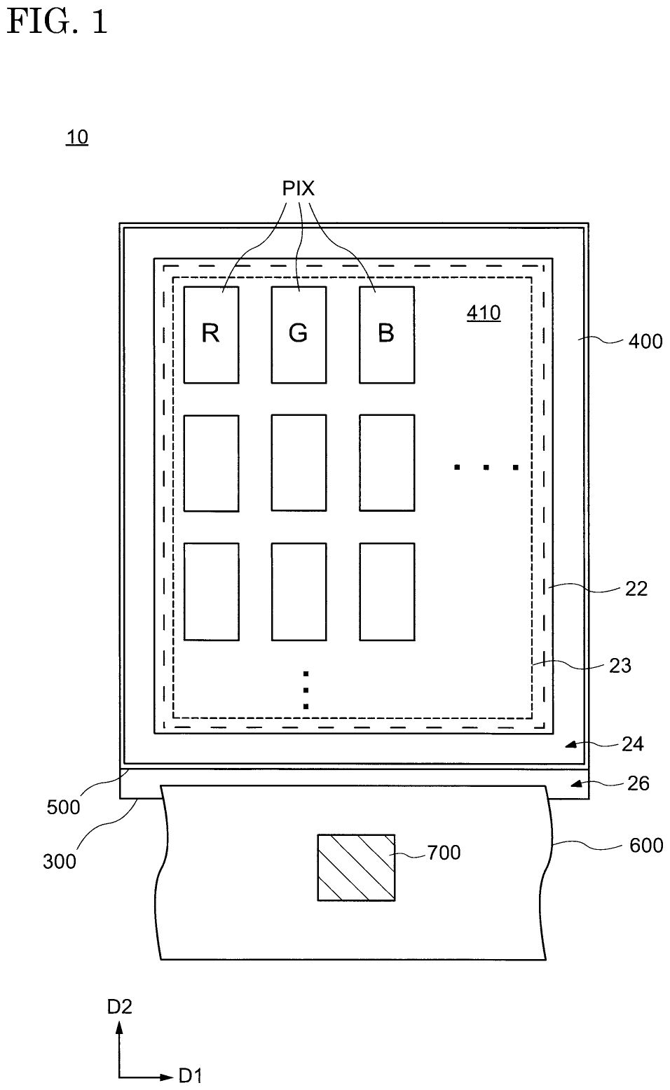

An outline of a display device 10 according to an embodiment of the present invention will be described with reference to FIG. 1 to FIG. 3. FIG. 1 is a plan view showing an outline of the display device 10 according to an embodiment of the present invention. As shown in FIG. 1, the display device 10 includes an array substrate 300, a seal part 400, a counter substrate 500, and a flexible printed circuit board 600 (FPC 600), and an IC chip 700. The array substrate 300 and the counter substrate 500 are bonded together by the seal part 400. In a liquid crystal region 22 surrounded by the seal part 400, a plurality of pixels PIX is arranged in a matrix along a direction D1 (row direction) and a direction D2 (column direction) intersecting the direction D1. The plurality of pixels PIX includes a red pixel R, a green pixel G, and a blue pixel B corresponding to a color filter arranged in a counter substrate. The direction D1 and the direction D2 may be orthogonal. Although not shown in FIG. 1, a direction perpendicular to a surface of the array substrate 300 will be described as a direction D3. The liquid crystal region 22 is a region that overlaps a liquid crystal element LE to be described later in a plan view. Hereinafter, a region including the plurality of pixels in the liquid crystal region 22 may be referred to as an image display region 23.

In addition, the display device 10 includes a backlight unit on the back of the array substrate 300, and when emitted light from the backlight unit is transmitted through the image display region 23, the transmitted light is modulated in each pixel PIX, so that an image is displayed.

A seal region 24 arranged with the seal part 400 is a region around the liquid crystal region 22. The FPC 600 is attached to a terminal region 26. The terminal region 26 is arranged in a region where the array substrate 300 does not overlap the counter substrate 500 and is arranged outside the seal region 24. In addition, the outside of the seal region 24 means the outside of the region arranged with the seal part 400 and the region surrounded by the seal part 400. The IC chip 700 is arranged on the FPC 600. The IC chip 700 supplies a signal for driving a pixel circuit of each pixel PIX. In the following explanation, the seal region 24, the outside of the seal region 24, and the terminal region 26 may be collectively referred to as a frame region. The IC chip 700 may be mounted on the frame region.

### 2. Circuit Configuration of Display Device

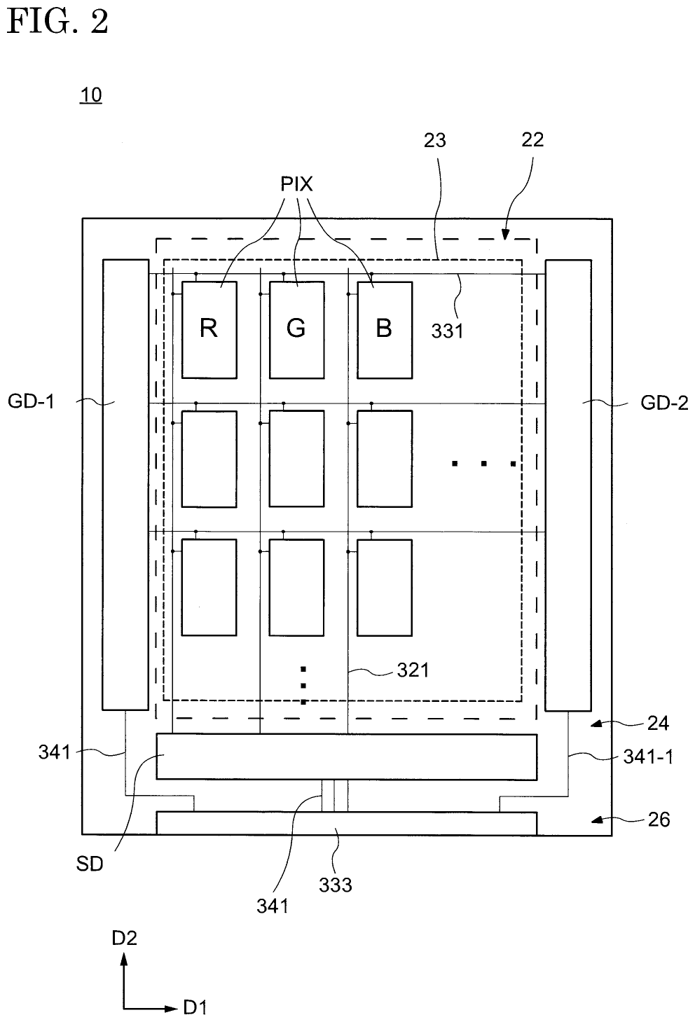

FIG. 2 is a block diagram showing a circuit configuration of the display device 10 according to an embodiment of the present invention. As shown in FIG. 2, a source driver circuit SD is arranged along the direction D1 with respect to the liquid crystal region 22 in which the pixel PIX is arranged, and gate driver circuits GD-1 and GD-2 are arranged along the direction D2 with respect to the liquid crystal region 22. The source driver circuit SD and the gate driver circuits GD-1 and GD-2 are arranged in the seal region 24. However, the region where the source driver circuit SD and the gate driver circuits GD-1 and GD-2 are arranged is not limited to the region 24, and may be any region outside the region where the pixel circuit of the pixel PIX is arranged. In addition, a configuration in which a source driver circuit is arranged inside the IC chip 700 may also be employed.

A source wiring 321 extends from the source driver circuit SD in the direction D2 and is connected to pixel circuits of the plurality of pixels PIX arranged in the direction D2. A gate wiring 331 extends from the gate driver circuit GD-1 or the gate driver circuit GD-2 in the direction D1 and is connected to pixel circuits of the plurality of pixels PIX arranged in the direction D1.

A terminal part 333 is arranged in the terminal region 26. The terminal part 333 and the source driver circuit SD are connected by a connecting wiring 341. Similarly, the terminal part 333 and the gate driver circuits GD-1 and GD-2 are connected by the connecting wiring 341. When the FPC 600 is connected to the terminal part 333, an external device to which the FPC 600 is connected is connected to a display device 20, and pixel circuits included in each pixel PIX arranged in the display device 10 are driven by a signal from the external device.

### 3. Pixel Circuit of Pixel PIX of Display Device

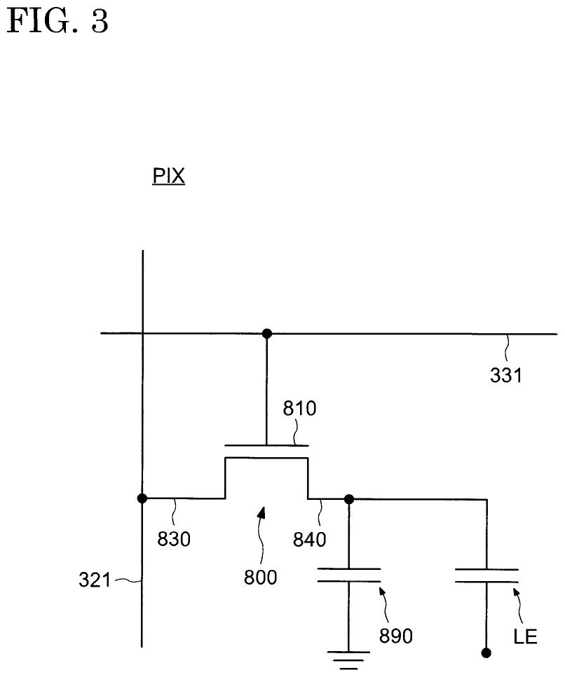

FIG. 3 is a circuit diagram showing a pixel circuit of the pixel PIX of the display device 10 according to an embodiment of the present invention. As shown in FIG. 3, the pixel circuit includes elements such as a transistor 800, a storage capacitor 890, and the liquid crystal element LE. Although details will be described later, one electrode of the liquid crystal element LE is a pixel electrode PTCO and the other electrode is a common electrode CTCO. In addition, one electrode of the storage capacitor 890 also serves as the pixel electrode PTCO, and the other electrode also serves as the common electrode CTCO. The transistor 800 includes a gate electrode 810, a source electrode 830, and a drain electrode 840. The first gate electrode 810 is connected to the gate wiring 331. The source electrode 830 is connected to the source wiring 321. The drain electrode 840 is connected to the storage capacitor 890 and the liquid crystal element LE. In the present embodiment, for convenience of explanation, 830B is referred to as a source electrode, and 840 is referred to as a drain electrode, but the function of each electrode as a source and the function as a drain may be interchanged.

### 4. Configuration of Display Device

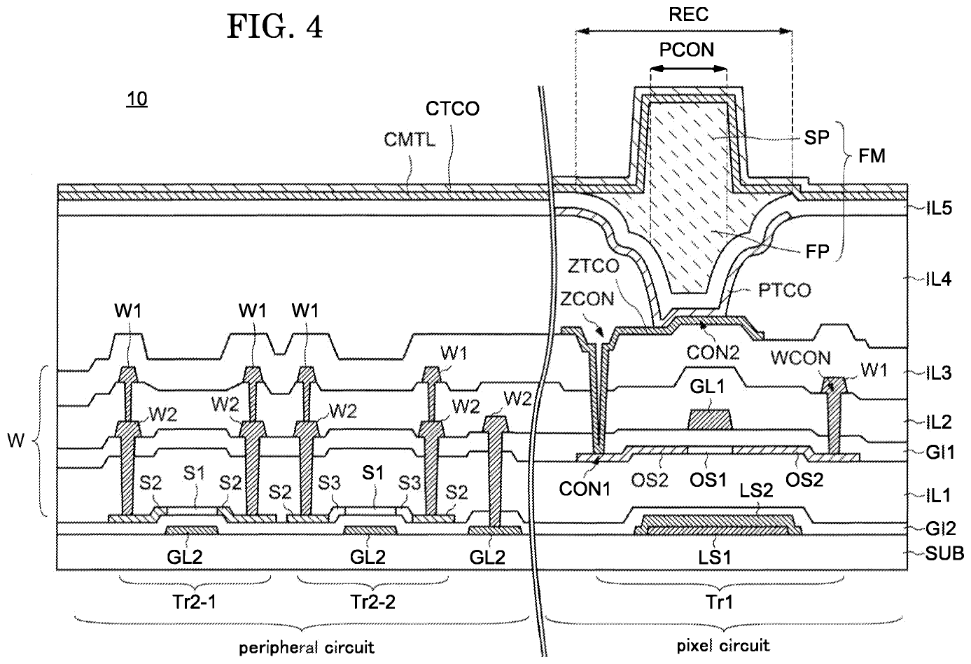

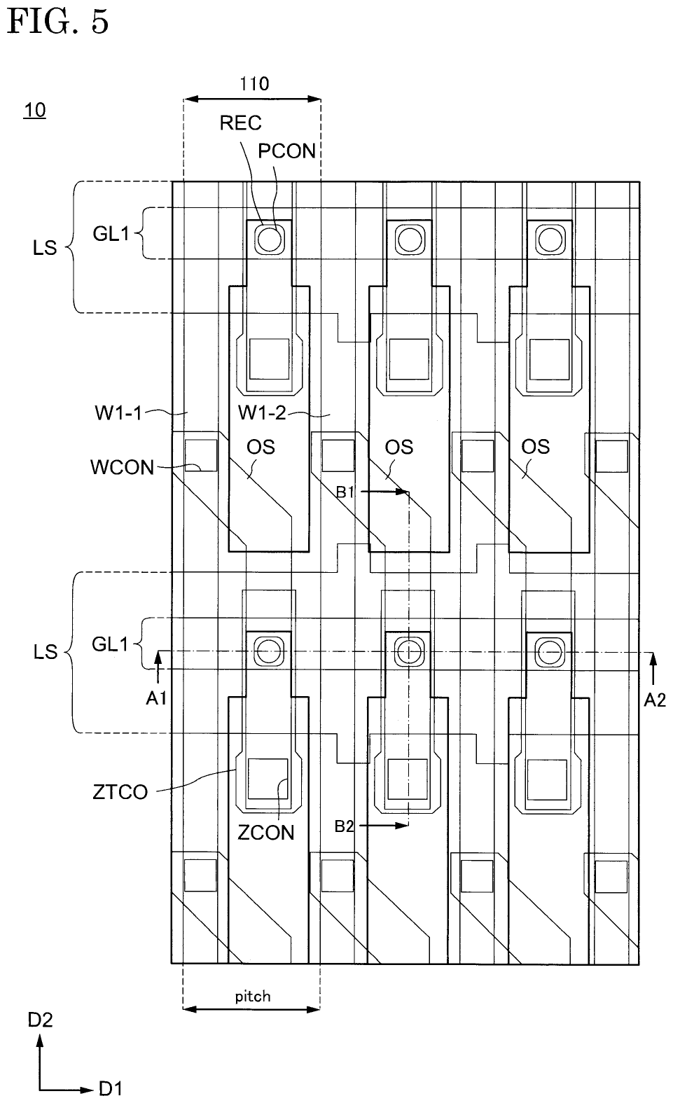

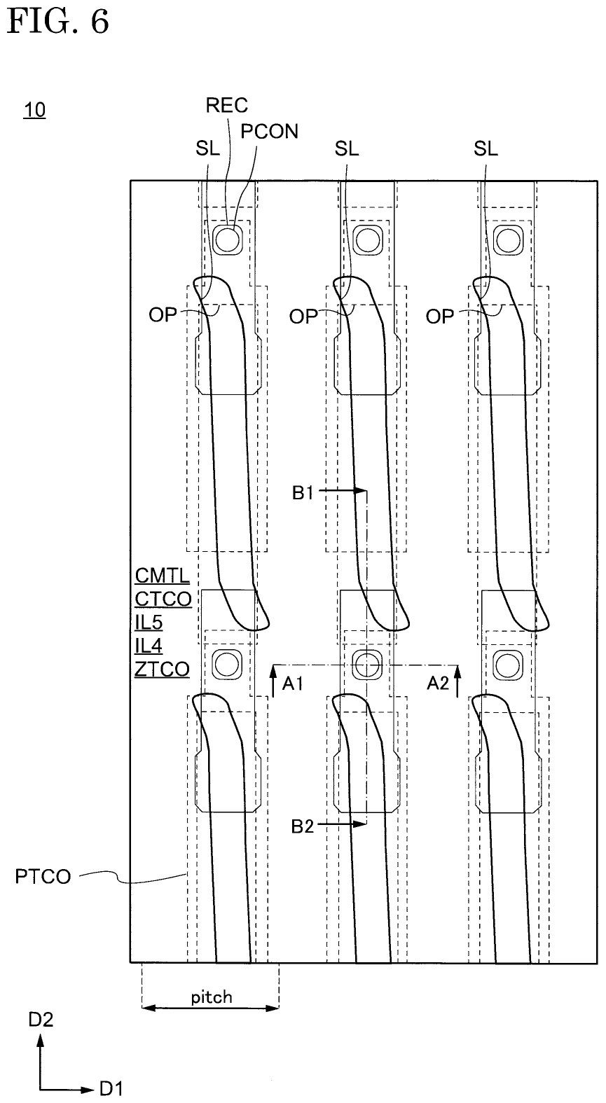

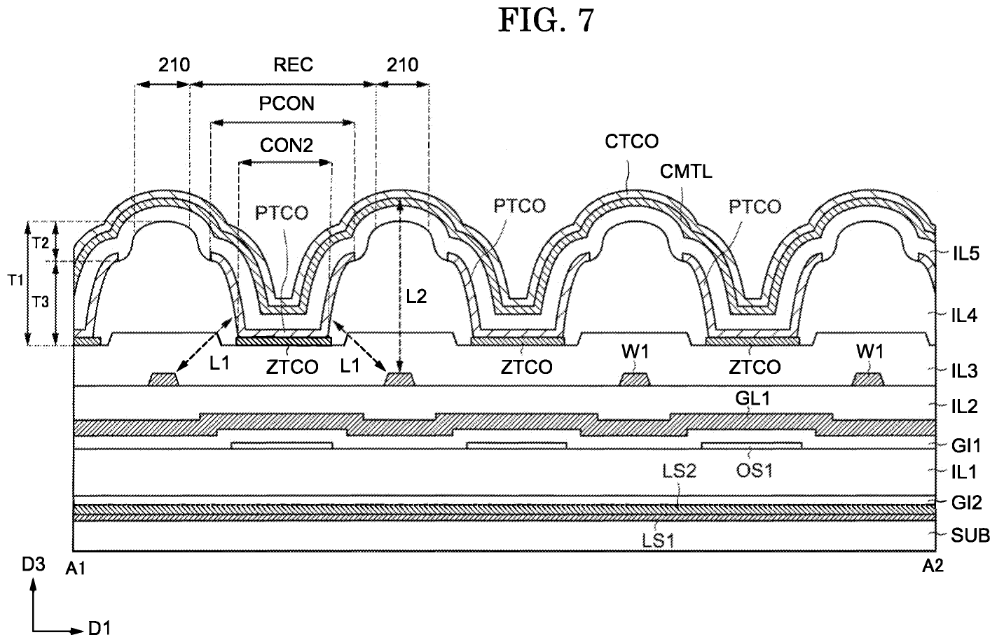

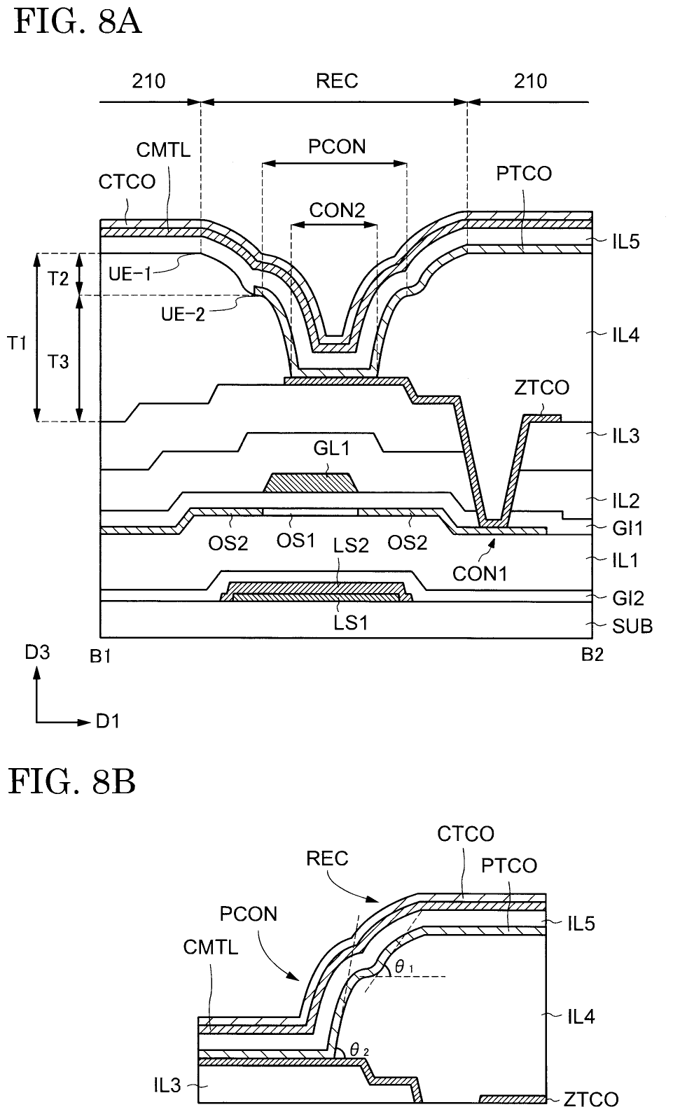

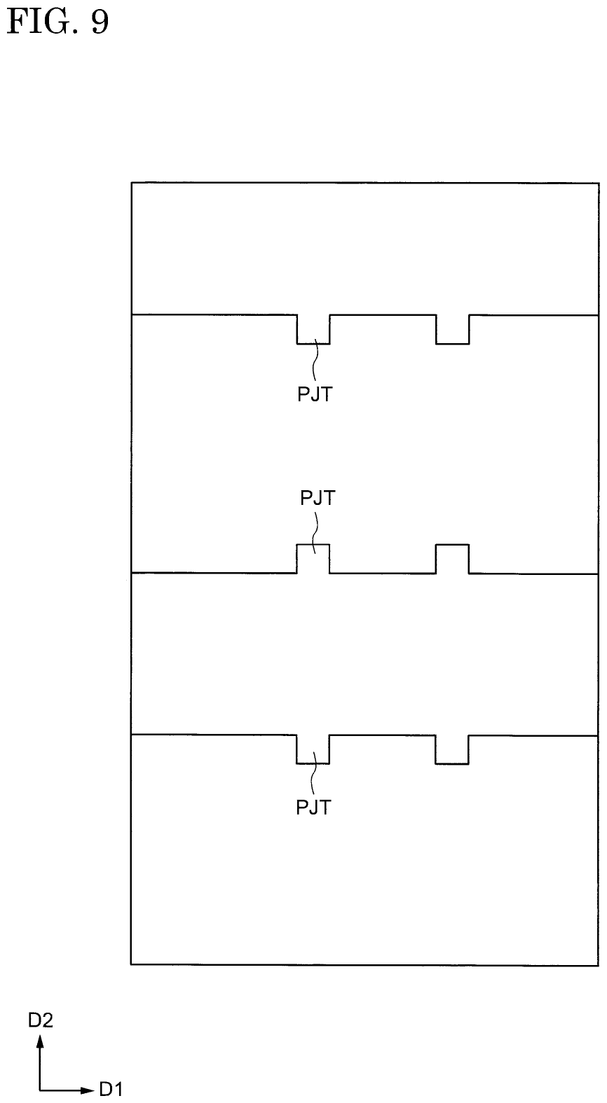

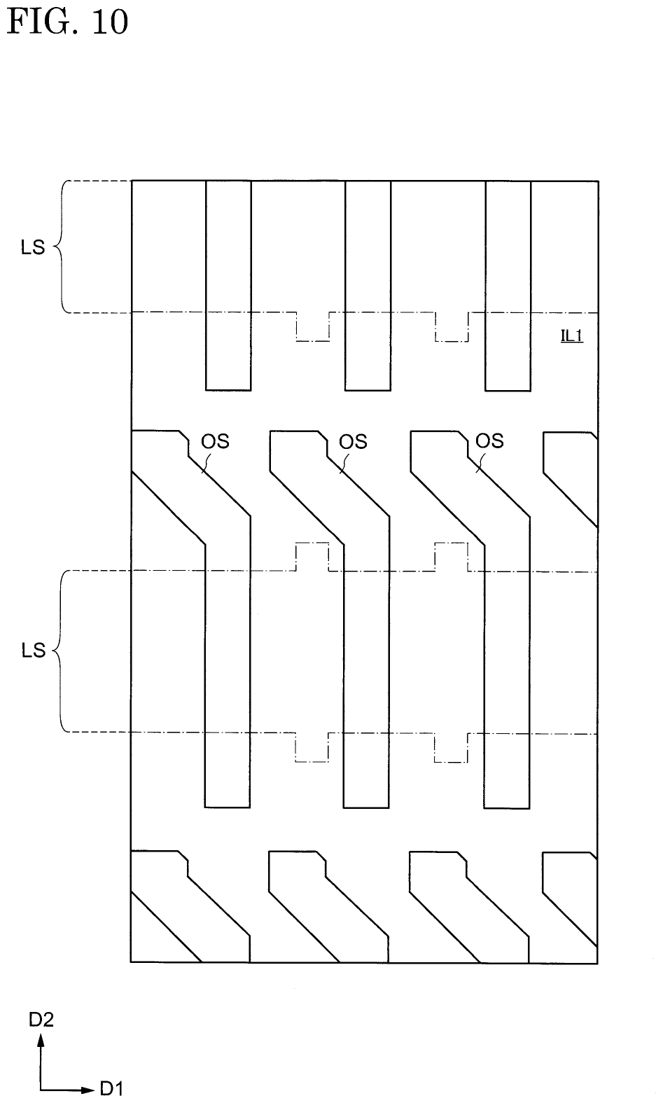

Detailed configurations of the display device 10 according to an embodiment of the present invention will be described with reference to FIG. 4 to FIG. 19. FIG. 4 is a cross-sectional view showing a configuration of the display device 10 according to an embodiment of the present invention. FIG. 5 and FIG. 6 are plan views showing a configuration of the display device 10 according to an embodiment of the present invention. FIG. 7 is a cross-sectional view at a line A1-A2 of the display device 10 shown in FIG. 5 and FIG. 6. FIG. 8A is a cross-sectional view at a line B1-B2 of the display device 10 shown in FIG. 5 and FIG. 6. FIG. 9 is a plan view at a border between the display region and the frame region. FIG. 10 to FIG. 19 are plan views illustrating layouts of each layer in the display device 10 according to an embodiment of the present invention. In addition, FIG. 4 is a cross-sectional view for explaining a layer structure of the display device 10, and a peripheral circuit and the pixel circuit are shown adjacently, but it is needless to say that the pixel circuit is actually arranged in the image display region and the peripheral circuit is arranged in the frame region outside the image display region, and these circuits are arranged apart from each other. In particular, in the pixel circuit of FIG. 4, a contact hole peripheral part in the pixel is mainly shown, and only part of a translucent region (opening region) that contributes to the display is shown.

As shown in FIG. 4, the display device 10 includes a substrate SUB, a transistor Tr1, a transistor Tr2, wirings W, a connecting electrode ZTCO, the pixel electrode PTCO, a common auxiliary electrode CMTL, and the common electrode CTCO. TCO is an abbreviation for Transparent Conductive Oxide. The transistor Tr1 is a transistor included in the pixel circuit of the pixel PIX of the display device 10. The transistor Tr2 is a transistor included in the peripheral circuit such as the source driver circuit SD or the gate driver circuits GD-1 and GD-2.

### 5. Configuration of Transistor Tr1

The transistor Tr1 (the transistor 800) has an oxide semiconductor layer OS, a gate insulating layer GI1, and a gate electrode GL1 (the first gate electrode 810). The gate electrode GL1 faces the oxide semiconductor layer OS. In addition, part of the gate wiring 331 functions as the gate electrode GL1. The gate insulating layer GI1 is arranged between the oxide semiconductor layer OS and the gate electrode GL1. In the present embodiment, although a top-gate transistor in which the oxide semiconductor layer OS is arranged closer to the substrate SUB than the gate electrode GL1 is exemplified, a bottom-gate transistor in which the positional relationship between the gate electrode GL1 and the oxide semiconductor layer OS is reversed may be used.

The oxide semiconductor layer OS includes oxide semiconductor regions OS1 and OS2. The oxide semiconductor region OS1 is an oxide semiconductor layer in a region overlapping the gate electrode GL1 in a plan view. The oxide semiconductor region OS1 functions as a semiconductor and is switched between a conductive state and a non-conductive state depending on a voltage supplied to the gate electrode GL1. That is, the oxide semiconductor region OS1 functions as a channel of the transistor Tr1. The oxide semiconductor region OS2 functions as a conductor.

An insulating layer IL2 is arranged above the gate electrode GL1. A wiring W1 (the source wiring 321) is arranged above the insulating layer IL2. The wiring W1 is connected to the oxide semiconductor region OS2 via a contact hole WCON arranged in the insulating layer IL2 and the gate insulating layer G11. A data signal related to the grayscale of the pixels is transmitted to the wiring W1. An insulating layer IL3 is arranged above the insulating layer IL2 and the wiring W1. The connecting electrode ZTCO (the drain electrode 840) is arranged above the insulating layer IL3. The connecting electrode ZTCO is connected to the oxide semiconductor region OS2 via a contact hole ZCON arranged in the insulating layers IL3 and IL2 and the gate insulating layer G11. The connecting electrode ZTCO is in contact with the oxide semiconductor region OS2 at a bottom part of the contact hole ZCON. The connecting electrode ZTCO is a transparent conductive layer.

A region where the connecting electrode ZTCO (also referred to as a first transparent conductive layer) is in contact with the oxide semiconductor region OS2 is referred to as a first contact region CON1. Although details will be described later, the connecting electrode ZTCO contacts the oxide semiconductor region OS2 in the first contact region CON1 that does not overlap the gate electrode GL1 and the wiring W1 in a plan view. In a plan view, the first contact region CON1 is included in the display region of the pixel.

For example, in the case where an ITO layer or other transparent conductive layer is formed so as to be in contact with a semiconductor layer such as a silicon layer, a surface of the semiconductor layer is oxidized by process gases and oxygen ions at the time of ITO deposition. Since the oxide layer formed on the surface of the semiconductor layer has a high resistance, the contacting resistance between the semiconductor layer and the transparent conductive layer increases. As a result, defects occur in the electrical contact between the semiconductor layer and the transparent electrode layer. On the other hand, even if the transparent conductive layer is formed to be in contact with the oxide semiconductor layer, the high resistance oxide layer as described above is not formed on the oxide semiconductor layer. Therefore, no defects occur in the electric contact between the oxide semiconductor layer and the transparent conductive layer.

An insulating layer IL4 is arranged above the connecting electrode ZTCO. The insulating layer IL4 relieves a step formed by a structure arranged below the insulating layer IL4. The insulating layer IL4 may be referred to as a planarization film. The pixel electrode PTCO (also referred to as a second transparent conductive layer) is arranged above the insulating layer IL4.

The pixel electrode PTCO is connected to the connecting electrode ZTCO via a contact hole PCON arranged in the insulating layer IL4. A region where the connecting electrode ZTCO and the pixel electrode PTCO are in contact is referred to as a contact region CON2. In a plan view, the contact region CON2 overlaps the gate electrode GL1. The pixel electrode PTCO is the transparent conductive layer.

As shown in FIG. 4, the insulating layer IL4 has a recess portion REC in a region overlapping the connecting electrode ZTCO. That is, the insulating layer IL4 has a region that is recessed at its surface. The contact hole PCON is arranged at a bottom part of the recess portion REC. In the present embodiment, although the recess portion REC and the contact hole PCON will be described separately, it can be said that the insulating layer IL4 has the contact hole PCON having a step. Specifically, the insulating layer IL4 has the contact hole PCON having an upper stage and a lower stage. The upper stage of the contact hole PCON has a wide opening area, and the lower stage has a narrow opening area. The recess portion REC and the contact hole PCON will be described in detail later.

An insulating layer IL5 is arranged above the pixel electrode PTCO and the insulating layer IL4. The insulating layer IL5 is also arranged on a side surface of the contact hole PCON and above the pixel electrode PTCO inside the contact hole PCON. A filling member FM is arranged above the insulating layer IL5 so as to fill the inside of the contact hole PCON. In a region where the filling member FM is arranged, the filling member FM has a projecting portion protruding above a top surface of the pixel electrode PTCO arranged above the insulating layer IL4. The projecting portion functions as a spacer SP. In addition, a part of the filling member FM that substantially coincides with the top surface of the pixel electrode PTCO or a top surface of the insulating layer IL5 arranged above the insulating layer IL4 is also referred to as a filling part FP.

The spacer SP is arranged for some of the pixels. For example, the spacer SP may be arranged for any one of the red pixel, the green pixel, and the blue pixel. However, the spacer SP may be arranged for all the pixels. A height of the spacer SP is half the height of a cell gap. A spacer is also arranged in the counter substrate, and the spacer of the counter substrate and the spacer SP overlap in a plan view. In addition, a configuration in which the height of the spacer SP corresponds to the cell gap can also be applied. A detailed configuration of the spacer SP will be described later in detail.

As shown in FIG. 4, the common auxiliary electrode CMTL and the common electrode CTCO (also referred to as a third transparent conductive layer) are arranged above the insulating layer IL5 and the spacer SP. The common electrode CTCO is arranged in contact with the common auxiliary electrode CMTL. The pixel electrode PTCO, the insulating layer IL5, and the common electrode CTCO constitute the storage capacitor 890. In addition, the common auxiliary electrode CMTL is arranged in contact with the filling member FM. The common auxiliary electrode CMTL and the common electrode CTCO have different planar patterns. The common auxiliary electrode CMTL is a metal layer. The common electrode CTCO is a transparent conductive layer. Electrical resistance of the common auxiliary electrode CMTL is lower than the electrical resistance of the common electrode CTCO. In addition, the common auxiliary electrode CMTL also functions as a light-shielding layer. For example, the common auxiliary electrode CMTL blocks light from adjacent pixels, thereby suppressing the occurrence of color mixing. In a plan view, the second contact region CON2 and the recess portion REC overlap the common auxiliary electrode CMTL. In the present embodiment, although a configuration in which the common electrode CTCO is arranged above the common auxiliary electrode CMTL is shown, it may be a configuration in which the common auxiliary electrode CMTL is arranged above the common electrode CTCO.

A light-shielding layer LS is arranged between the transistor Tr1 and the substrate SUB. In the present embodiment, the light-shielding layers LS1 and LS2 are arranged as the light-shielding layer LS. However, the light-shielding layer LS may be formed of the light-shielding layer LS1 only or LS2 only. In a plan view, the light-shielding layer LS is arranged in a region where the gate electrode GL1 and the oxide semiconductor layer OS overlap. In other words, in a plan view, the light-shielding layer LS is arranged in a region overlapping the oxide semiconductor region OS1. The light-shielding layer LS suppresses the light entering from the substrate SUB side from reaching the oxide semiconductor region OS1. In the case where a conductive layer is used as the light-shielding layer LS, a voltage may be applied to the light-shielding layer LS to control the oxide semiconductor region OS1. In the case where the voltage is applied to the light-shielding layer LS, the light-shielding layer LS and the gate electrode GL1 may be connected in the frame region. In a plan view, the first contact region CON1 is arranged in a region not overlapping the light-shielding layer LS. In addition, in a plan view, the second contact region CON2 and the recess portion REC are arranged in a region overlapping the light-shielding layer LS.

### 6. Configuration of Transistor Tr2

The transistor Tr2 has a p-type transistor Tr2-1 and an n-type transistor Tr2-2.

Both the p-type transistor Tr2-1 and the n-type transistor Tr2-2 have a gate electrode GL2, a gate insulating layer GI2, and a semiconductor layer S. The gate electrode GL2 faces the semiconductor layer S. The gate insulating layer GI2 is arranged between the semiconductor layer S and the gate electrode GL2. In the present embodiment, although a bottom-gate transistor in which the gate electrode GL2 is arranged closer to the substrate SUB than the semiconductor layer S is exemplified, a top-gate transistor in which the positional relationship between the gate electrode GL2 and the semiconductor layer S is reversed may be used.

The semiconductor layer S of the p-type transistor Tr2-1 includes semiconductor regions S1 and S2. The semiconductor layer S of the n-type transistor Tr2-2 includes the semiconductor regions S1, S2, and S3. The semiconductor region S1 is a semiconductor region in the region overlapping the gate electrode GL2 in a plan view. The semiconductor region S1 functions as a channel of the transistor Tr2-1. The semiconductor region S2 functions as a conductor. The semiconductor region S3 functions as a conductor having higher resistance than the semiconductor region S2. The semiconductor region S3 suppresses hot carrier degradation by attenuating hot carriers entering the semiconductor region S1.

An insulating layer IL1 and the gate insulating layer GI1 are arranged above the semiconductor layer S. In the transistor Tr2, the gate insulating layer GI1 simply functions as an interlayer film. A wiring W2 is arranged above these insulating layers. The wiring W2 is connected to the semiconductor layer S via an opening arranged in the insulating layer IL1 and the gate insulating layer G11. The insulating layer IL2 is arranged above the wiring W2. The wiring W1 is arranged above the insulating layer IL2. The wiring W1 is connected to the wiring W2 via an opening (also referred to as a contact hole) arranged in the insulating layer IL2.

The gate electrode GL2 and the light-shielding layer LS2 are the same layer. The wiring W2 and the gate electrode GL1 are the same layer. The same layer means that a plurality of members is formed by patterning one layer.

### 7. Influence of Parasitic Capacitance

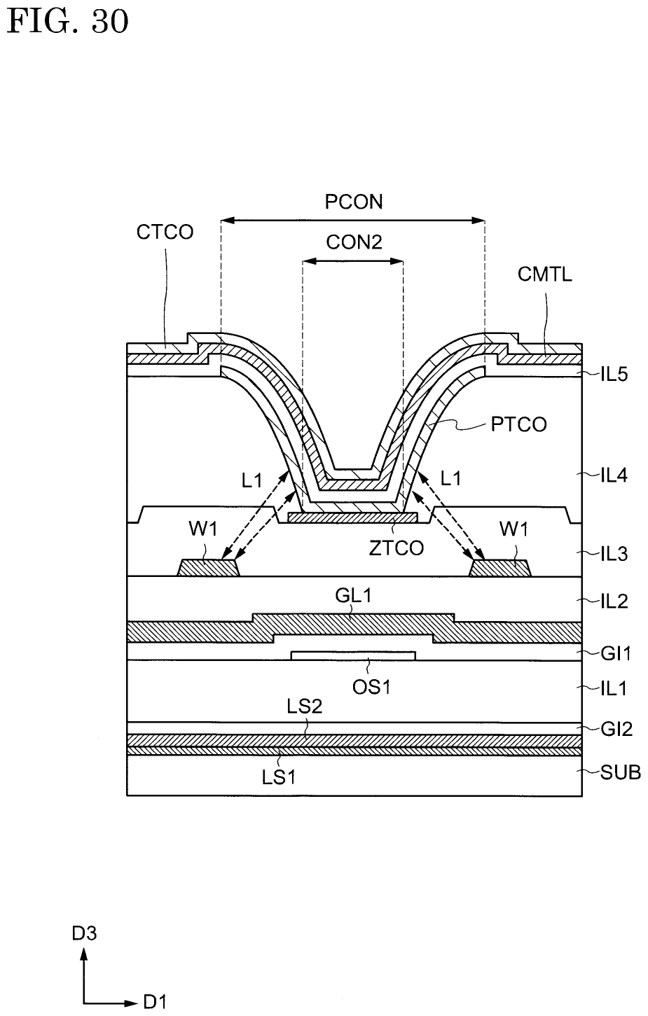

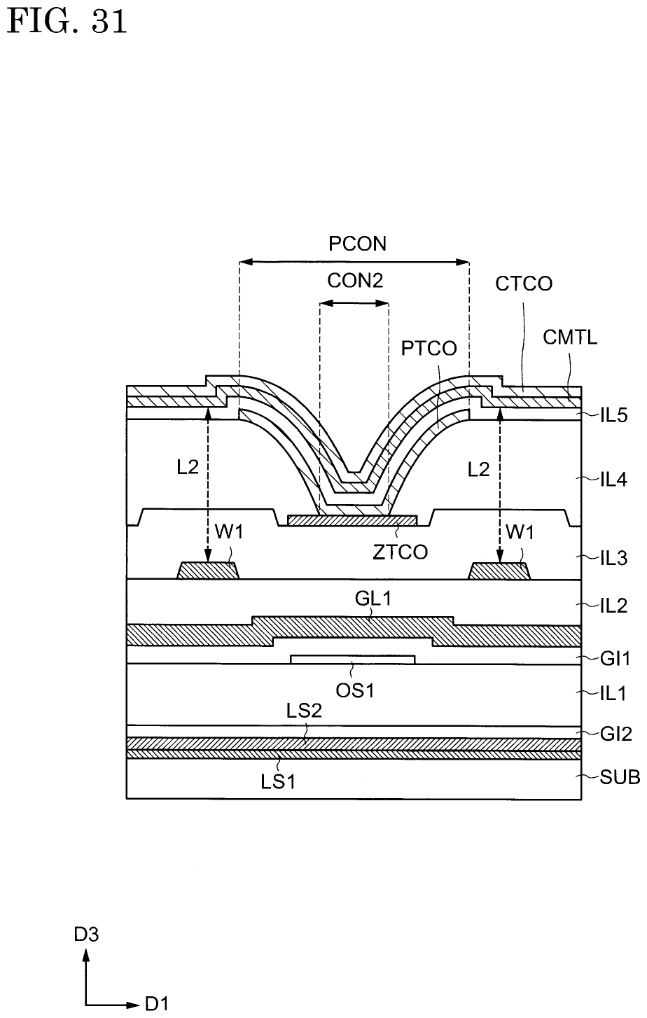

The influence of parasitic capacitance formed by the wiring W1, the pixel electrode PTCO, and the common electrode CTCO will be described with reference to FIG. 30 and FIG. 31. FIG. 30 and FIG. 31 are diagrams of the second contact region CON2 in which the connecting electrode ZTCO and the pixel electrode PTCO are in contact with each other and cut along the direction D1. In a display device such as a head-mounted display, a high-definition display in which the number of pixels is increased is desired. In order to achieve high definition of a pixel, parasitic capacitance (see FIG. 30) formed between the wiring W1 and the pixel electrode PTCO and parasitic capacitance (see FIG. 31) formed between the wiring W1 and the common electrode CTCO are problematic.

In order to reduce the parasitic capacitance formed between the wiring W1 and the common electrode CTCO, a distance between the wiring W1 and the common electrode CTCO may be increased. In this case, the insulating layer IL4 may be made thicker. However, when the thickness of the insulating layer IL4 is increased, a hole diameter (a hole diameter on the top surface of the insulating layer IL4) of the contact hole PCON tends to increase. Due to this effect, as shown in FIG. 30, the hole diameter of the contact hole PCON increases, so that an angle of a side wall of the contact hole PCON decreases (an inclination of the side wall becomes loose). As a result, a distance L1 between the wiring W1 and the pixel electrode PTCO covering the side surface of the contact hole PCON becomes closer in the direction D1, so that the parasitic capacitance between them becomes large to an extent that cannot be ignored. An attempt to drive the pixel at high speed in such a state increases the load between the wiring W1 and the pixel electrode PTCO, thereby increasing power consumption.

In order to reduce the parasitic capacitance between the wiring W1 and the pixel electrode PTCO, the distance between the wiring W1 and the pixel electrode PTCO may be increased. In this case, the hole diameter of the contact hole PCON may be reduced, but in order to reduce the hole diameter of the contact hole PCON, the thickness of the insulating layer IL4 needs to be reduced. The hole diameter of the contact hole PCON can be reduced, and the angle of the sidewall of the contact hole PCON can be reduced. On the other hand, since the thickness of the insulating layer IL4 is small, as shown in FIG. 31, a distance L2 between the wiring W and the common electrode CTCO in the direction D1 becomes closer, so that a parasitic capacitance is formed. In an attempt to drive the pixel at high speed in such a state, the potential of the pixel electrode PTCO becomes higher than the original potential due to the potential of the wiring W1 by the capacitive coupling caused by the parasitic capacitance. Therefore, variable crosstalk occurs in the display device, and the display quality of the display device is degraded.

As described above, in order to improve the definition of the pixel, there is a limitation in the form of the contact hole for connecting the connecting electrode ZTCO and the pixel electrode PTCO.

As described above, in order to achieve high definition of a pixel, it is required to suppress the formation of a parasitic capacitance caused by the contact hole connecting the connecting electrode ZTCO and the pixel electrode PTCO.

In the display device 20 according to an embodiment of the present invention, the hole diameter of the contact hole PCON can be reduced and the angle of the sidewall of the contact hole PCON can be increased without unnecessarily reducing the thickness of the insulating layer IL4. This suppresses an increase in power consumption of the display device 20. In addition, the occurrence of crosstalk in the display device 20 is suppressed.

FIG. 7 is a cross-sectional view at a line A1-A2 of the display device shown in FIG. 5 and FIG. 6. FIG. 8A is a cross-sectional view at a line B1-B2 of the display device shown in FIG. 5 and FIG. 6. FIG. 8B is a diagram illustrating a vicinity of the contact hole PCON of the cross-sectional view shown in FIG. 8A. As shown in FIG. 7 and FIG. 8A, the insulating layer IL4 has the recess portion REC in a region overlapping the connecting electrode ZTCO. The contact hole PCON is arranged at the bottom part of the recess portion REC arranged in the insulating layer IL4. The connecting electrode ZTCO and the pixel electrode PTCO are connected at the contact hole PCON.

As shown in FIG. 5, in a plan view, an interval pitch (also referred to as a pixel pitch) between a wiring W1-1 and a wiring W1-2 of two pixels adjacent in the direction D1 is 4 μm or more and 8 μm or less. As shown in FIG. 5 and FIG. 6, in a plan view, although the shape of the recess portion REC is a square shape with rounded corners, an embodiment of the present invention is not limited to this. The shape of the recess portion REC may be a circular shape or a polygonal shape. In addition, the diameter of a circumscribed circle surrounding the recess portion REC is preferably 60% or less with respect to the interval pitch between the wiring W1-1 and the wiring W1-2. As shown in FIG. 5 and FIG. 6, in a plan view, the shape of the contact hole PCON is circular. The hole diameter of the contact hole PCON is preferably 40% or more with respect to the interval pitch between the wiring W1-1 and the wiring W1-2. In addition, in a plan view, the contact hole PCON may be formed inside the recess portion REC. The shape of the recess portion REC and the shape of the contact hole PCON may be the same or different.

As shown in FIG. 7, the total thickness of the insulating layer IL4 corresponds to a thickness T1. In addition, in the insulating layer IL4, a depth of the recess portion REC corresponds to a thickness T2 of the insulating layer IL4. Further, the thickness of the insulating layer IL4 to the bottom part of the recess portion REC corresponds to a thickness T3 of the insulating layer IL4. In other words, the depth of the contact hole PCON corresponds to the thickness T3 of the bottom part of the recess portion REC of the insulating layer IL4. The thickness T3 of the insulating layer IL4 to the bottom part of the recess portion REC is 70% or more and 75% or less with respect to the thickness T1 of the insulating layer IL4 where no recess portion REC is arranged.

As shown in FIG. 8B, in a cross-sectional view, the recess portion REC has a slope in which an angle of the substrate with respect to the horizontal plane is θ₁. The contact hole PCON is arranged at the bottom part of the recess portion REC. In addition, as shown in FIG. 8B, in a cross-sectional view, the contact hole PCON has a slope in which the angle of the substrate with respect to the horizontal plane is θ₂. In this case, the angle θ₁ is preferably smaller than the angle θ₂. Since the angle θ₁ is small, the distance L1 between the pixel electrode PTCO and the wiring W1 arranged in the contact hole PCON can be increased.

The insulating layer IL4 is formed using an organic insulating material. As shown in FIG. 8A, although an upper end portion UE-1 of the recess portion REC arranged in the insulating layer IL4 is curved and an upper end portion of the contact hole PCON is curved, an embodiment of the present invention is not limited to this. The recess portion REC and the contact hole PCON in the insulating layer IL4 may have a tapered shape having an angle with respect to the horizontal plane of the substrate.

In the display device according to the present embodiment, arranging the contact hole PCON at the bottom part of the recess portion REC arranged in the insulating layer IL4 makes it possible to reduce the hole diameter of the contact hole PCON without unnecessarily reducing the thickness T1 of the insulating layer IL4. In addition, the angle of the side wall of the contact hole PCON can be increased. As a result, it is possible to suppress the distance L1 between the wiring W1 and the pixel electrode PTCO covering the side wall of the contact hole PCON from being reduced in the direction D1. As a result, it is possible to suppress the formation of the parasitic capacitance by the wiring W1 and the pixel electrode PTCO on the side surface of the contact hole PCON. Therefore, even when the pixel is driven at high speed, it is possible to suppress an increase in the load between the wiring W1 and the pixel electrode PTCO. Therefore, the power consumption of the display device can be reduced.

In addition, since the thickness T1 of the insulating layer IL4 can be sufficiently increased, it is possible to suppress the distance L2 between the wiring W1 and the common electrode CTCO from being reduced. As a result, it is possible to suppress the formation of the parasitic capacitance by the wiring W1 and the common electrode CTCO. Therefore, even when the pixel is driven at high speed, capacitive coupling caused by the parasitic capacitance can suppress the fluctuation in the potential of the pixel electrode PTCO due to the potential of the wiring W1. Therefore, it is possible to suppress the occurrence of crosstalk in the display device.

### 8. Plane Layout of Display Device

A plane layout of the pixels of the display device 10 will be described with reference to FIG. 9 to FIG. 19. FIG. 9 to FIG. 19 show planar layouts of the pixels in the case where the spacer SP is not arranged.

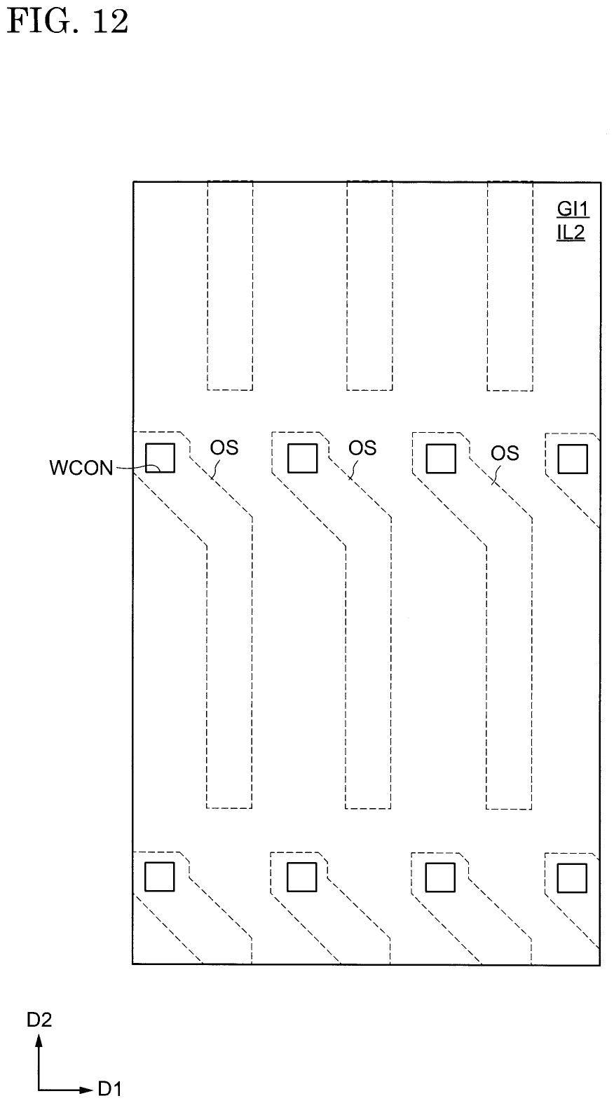

As shown in FIG. 4 and FIG. 9, the light-shielding layer LS extends in the direction D1 and is arranged in common with the pixels arranged in the direction D1. The shapes of the light-shielding layer LS may be different depending on the pixels. For example, the shape of the light-shielding layer LS may be different between the region where the spacer SP is arranged and the region where the spacer SP is not arranged. The shape of the light-shielding layer LS in the region where the spacer SP is arranged will be described later. In the present embodiment, a projecting portion PJT protruding from part of the light-shielding layer LS extending in the direction D1 toward the direction D2 intersecting the direction D1 is arranged. As shown in FIG. 12, the light-shielding layer LS is arranged in a region including the region where the gate electrode GL1 and the oxide semiconductor layer OS overlap in a plan view. In addition, the gate electrode GL1 may also be referred to as a “gated line.”

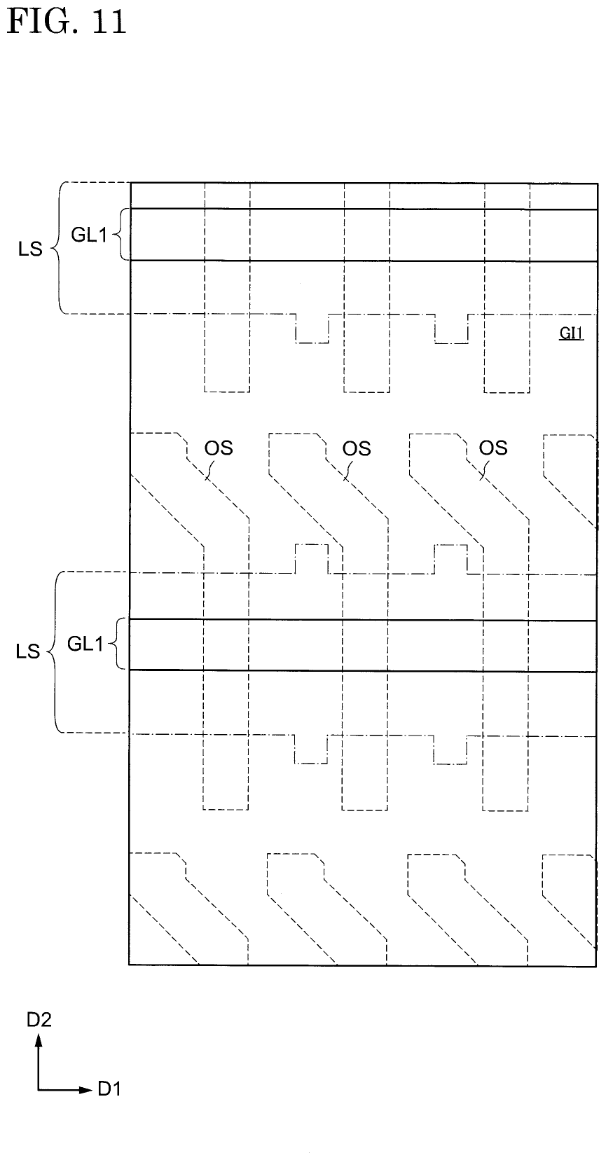

As shown in FIG. 4, FIG. 10, and FIG. 11, the oxide semiconductor layer OS extends in the direction D2. The gate electrode GL1 extends in the direction D1 and intersects the oxide semiconductor layer OS. A pattern of the gate electrode GL1 is arranged inside a pattern of the light-shielding layer LS.

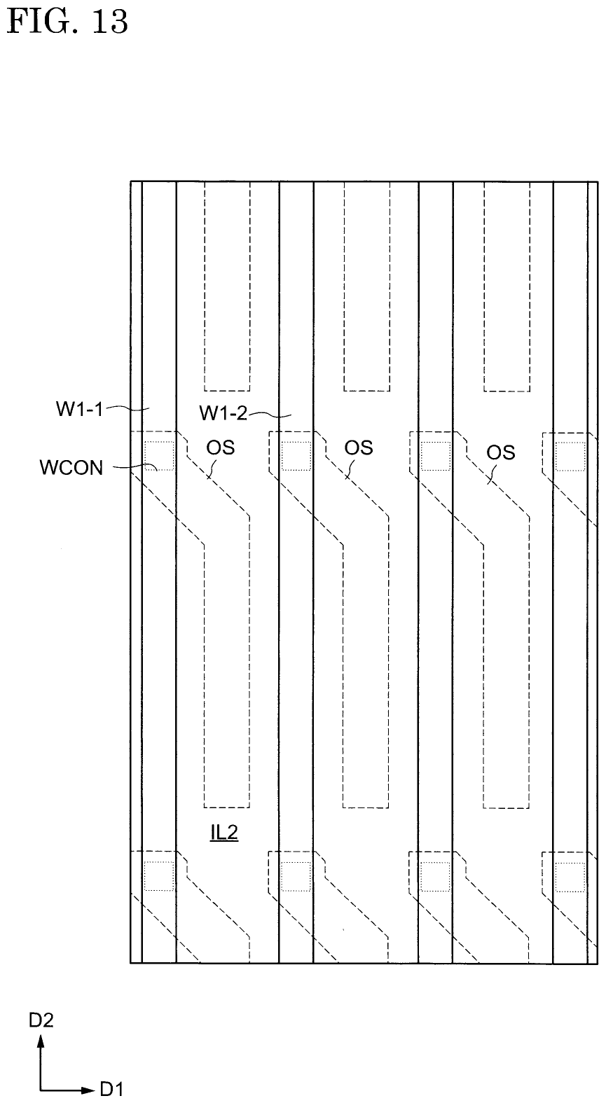

As shown in FIG. 4, FIG. 12, and FIG. 13, the contact hole WCON is arranged in a region overlapping the wiring W1 near an upper end of a pattern of the oxide semiconductor layer OS. The contact hole WCON is formed in the gate insulating layer GI1 and the insulating layer IL2. The wiring W1 is formed above the insulating layer IL2. The main part of the pattern of the oxide semiconductor layer OS extends in the direction D2 between the adjacent wiring W1. The remaining part of the pattern of the oxide semiconductor layer OS extends from the main part toward the region of the contact hole WCON in a direction oblique to the direction D1 and the direction D2.

As shown in FIG. 4 and FIG. 13, a plurality of wirings W1 extends in the direction D2. If two adjacent wirings need to be described separately, the two adjacent wirings W1 are referred to as the first wiring W1-1 and the second wiring W1-2. In this case, it can be said that the main part of the oxide semiconductor layer OS extends in the direction D2 between the first wiring W1-1 and the second wiring W1-2 and intersects the gate electrode GL1.

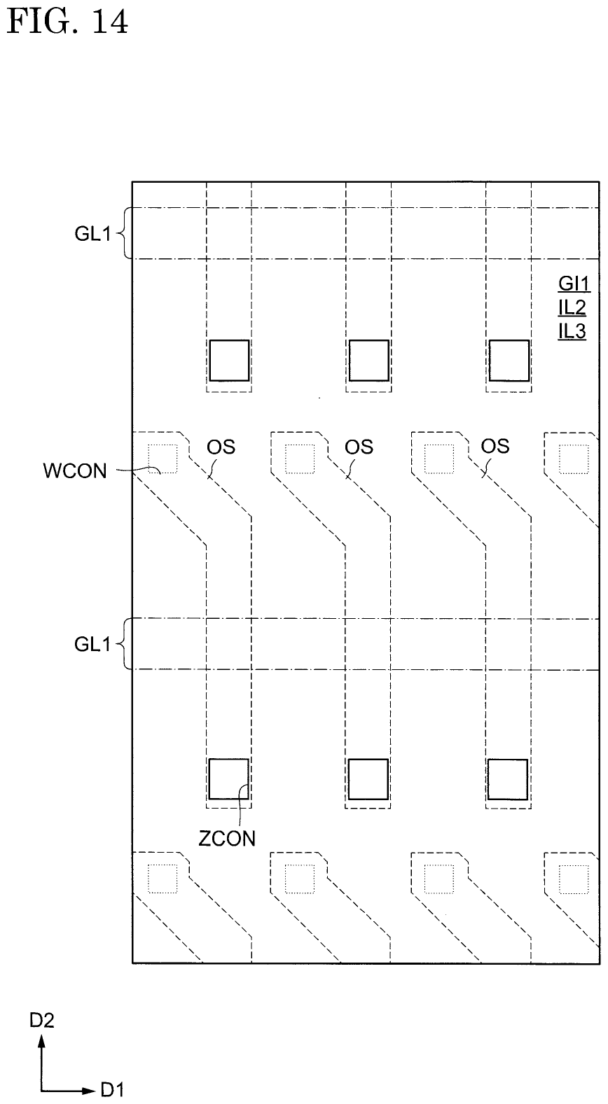

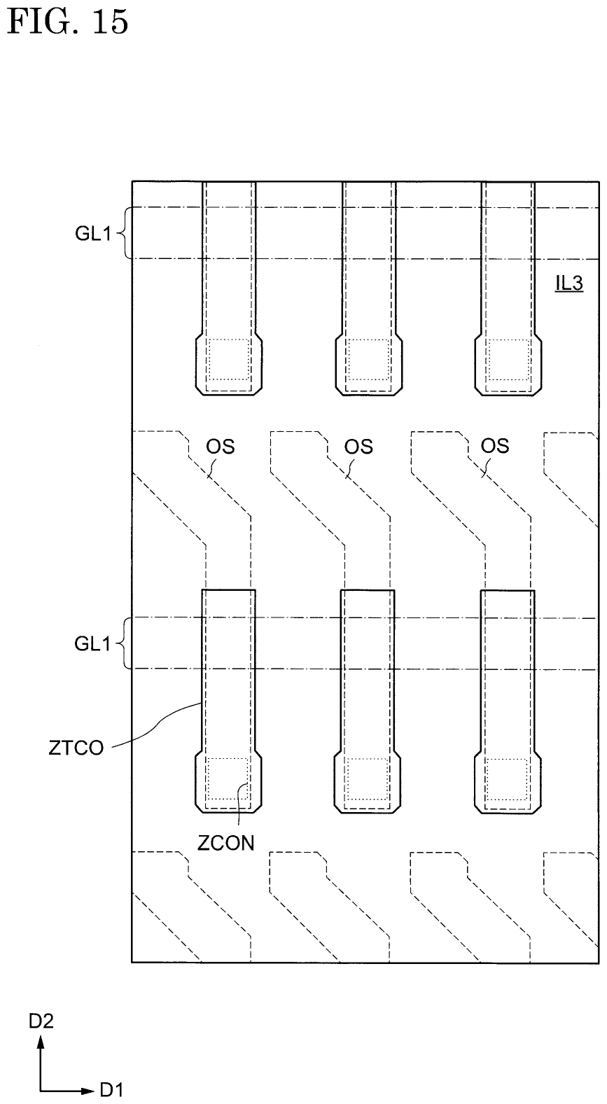

As shown in FIG. 4, FIG. 14, and FIG. 15, the contact hole ZCON is arranged near a lower end of the pattern of the oxide semiconductor layer OS. The contact hole ZCON is formed in the gate insulating layer GI1, and the insulating layers IL2 and IL3. The contact hole ZCON is arranged in the region overlapping the pattern of the oxide semiconductor layer OS and in the region not overlapping the gate electrode GL1. The contact hole ZCON is arranged in the region overlapping the connecting electrode ZTCO. The connecting electrode ZTCO is formed above the insulating layer IL3. The connecting electrode ZTCO overlaps the gate electrode GL1 and the oxide semiconductor layer OS between the first wiring W1-1 and the second wiring W1-2. Therefore, the connecting electrode ZTCO is in contact with the oxide semiconductor layer OS in the contact hole ZCON (the first contact region CON1) not overlapping the gate electrode GL1.

As shown in FIG. 4, FIG. 14, and FIG. 15, the oxide semiconductor layer OS is in contact with the wiring W1 at the opposite side of the contact hole ZCON (the first contact region CON1) with respect to the gate electrode GL1. The contact hole ZCON does not overlap the light-shielding layer LS.

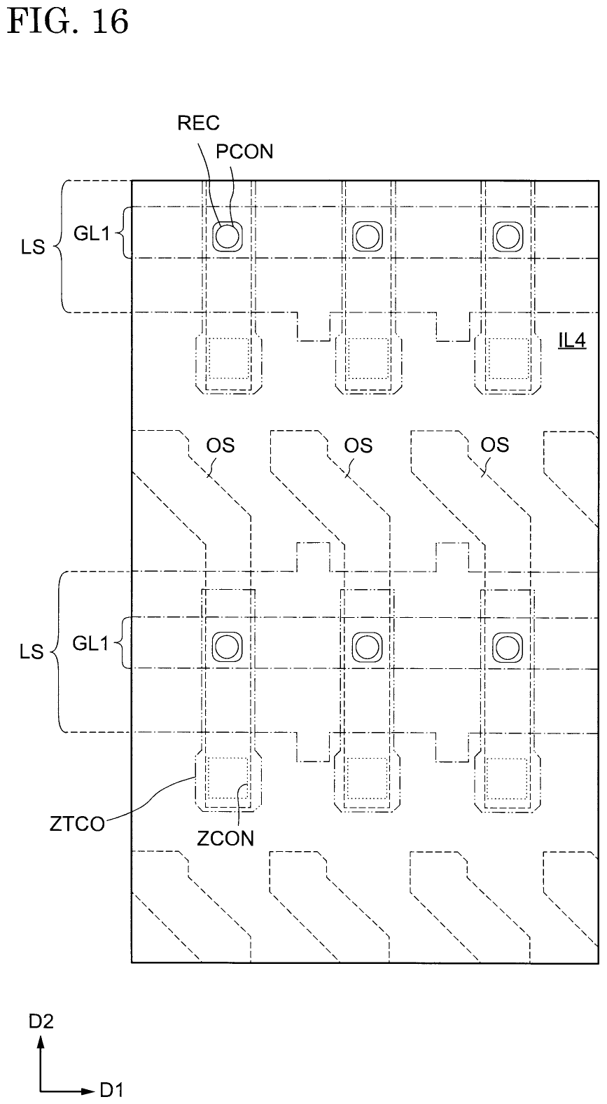

As shown in FIG. 4 and FIG. 16, the recess portion REC and the contact hole PCON are arranged near an upper end of a pattern of the connecting electrode ZTCO. The recess portion REC and the contact hole PCON are formed in the insulating layer IL4. The recess portion REC and the contact hole PCON are arranged in a region overlapping the pattern of the gate electrode GL1 and the pattern of the connecting electrode ZTCO. The connecting electrode ZTCO is exposed inside the contact hole PCON.

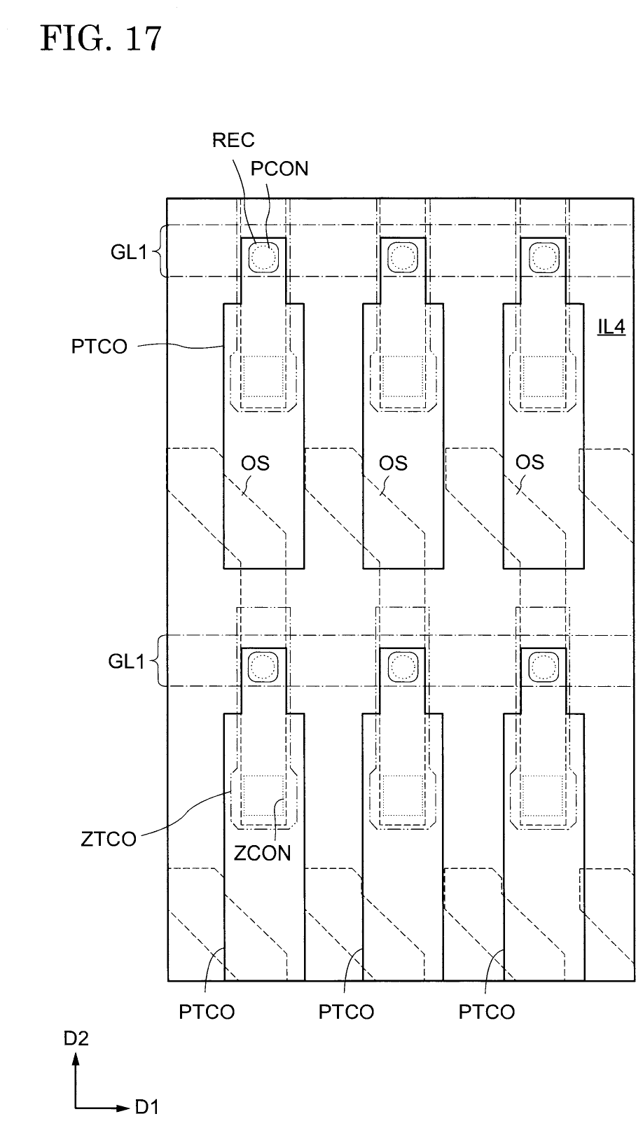

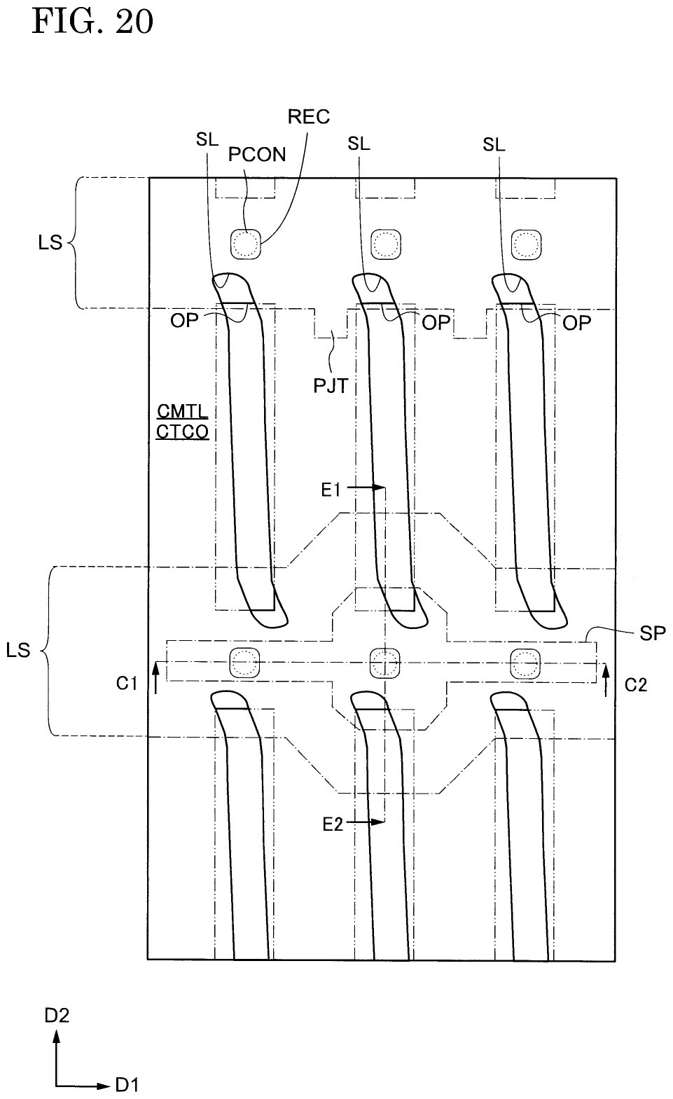

As shown in FIG. 4 and FIG. 17, the pixel electrode PTCO is arranged in a region overlapping the contact hole PCON. The pixel electrode PTCO is formed above the insulating layer IL4 and inside the recess portion REC and the contact hole PCON. The connecting electrode ZTCO and the pixel electrode PTCO are connected inside the contact hole PCON. The pixel electrode PTCO overlaps the gate electrode GL1, the oxide semiconductor layer OS, and the connecting electrode ZTCO between the first wiring W1-1 and the second wiring W1-2. Therefore, the pixel electrode PTCO is in contact with the connecting electrode ZTCO in the contact hole PCON (the second contact region CON2) overlapping the gate electrode GL1. In addition, a region of the rectangular pixel electrode PTCO arranged on the top surface of the insulating layer IL4 is far from the wiring W1 because the insulating layer IL4 is interposed therebetween, so that it is hardly affected by the potential of the wiring W1. On the other hand, the region of the pixel electrode PTCO that is in contact with the connecting electrode ZTCO is positioned at the bottom part of an opening groove, so that the insulating layer IL4 is not interposed and is relatively close to the wiring W1. Therefore, in order to increase the distance between the wiring W1 and the pixel electrode PTCO, a width (a length in the direction D1) of the pixel electrode PTCO in the region in contact with the connecting electrode ZTCO may be smaller than a width (a length in the direction D1) of the pixel electrode PTCO in the other regions. In addition, in the region where the spacer SP is arranged in the image display region, the filling member FM is arranged above the insulating layer IL5. The filling member FM will be described in detail after FIG. 20.

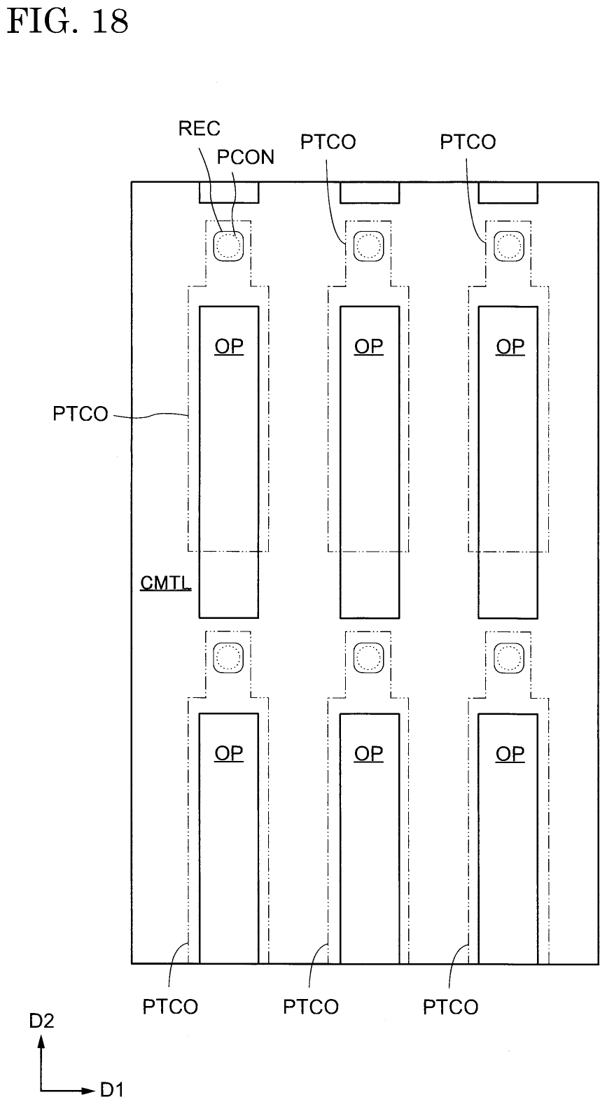

As shown in FIG. 4 and FIG. 18, the common auxiliary electrode CMTL is arranged in a grid pattern overlapping part of the pixel electrode PTCO of each of the plurality of pixels, and an opening OP is formed at a position facing each pixel electrode PTCO. Specifically, the common auxiliary electrode CMTL is arranged in common for a plurality of or all pixels without being divided within the image display region, overlaps the recess portion REC and the contact hole PCON of each pixel, and also overlaps part of an edge portion of each pixel electrode PTCO. Therefore, in the recess portion REC and the contact hole PCON, the common auxiliary electrode CMTL overlaps the pixel electrode PTCO. In addition, the common auxiliary electrode CMTL also overlaps the gate electrode GL1 in a plan view. On the other hand, the common auxiliary electrode CMTL is opened so that the pixel electrode PTCO including the contact hole ZCON is exposed. That is, the contact hole ZCON (the first contact region CON1) is included in the display region. The term “display region” as used herein means a region that allows a user to visually recognize light from the pixel when viewed in units of pixels. For example, a region that is shielded by the metal layer and is not visible to the user is not included in the display region. In other words, the display region may be referred to as the “translucent region (or the opening region)”. The common auxiliary electrode CMTL is arranged along the direction D1 and the direction D2. In addition, the common auxiliary electrode CMTL is arranged so as to overlap the gate wiring GL and the wiring W1. The common auxiliary electrode CMTL has a light-shielding function and can suppress light irradiation to the channel of the oxide semiconductor layer OS. Therefore, in the display device 10 including such a common auxiliary electrode CMTL, the characteristics of the transistor Tr1 are stabilized and the reliability is improved.

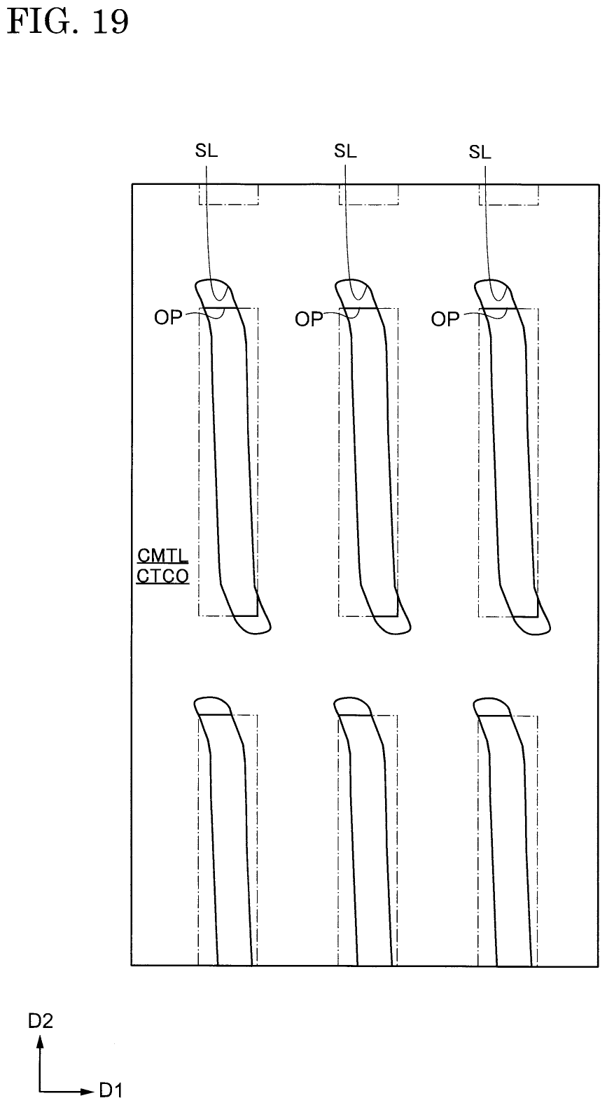

As shown in FIG. 19, the common electrode CTCO is commonly arranged for a plurality of or all pixels without being divided in the image display region 23. The common electrode CTCO overlaps the pixel electrode PTCO. In the common electrode CTCO, a slit SL is arranged in a region corresponding to each opening OP. The slit SL has a curved shape (a longitudinally long S-shape). A tip of the slit SL has a shape in which a width perpendicular to an extension direction of the tip is reduced. In addition, one tip of the slit SL overlaps the common auxiliary electrode CMTL and overlaps the pixel electrode PTCO. The other tip of the slit SL is positioned inside the opening OP but does not overlap the pixel electrode PTCO.

### 9. Configuration of Spacer

A configuration of the spacer SP arranged in the array substrate will be described with reference to FIG. 20 to FIG. 22. The spacer SP is arranged in the array substrate and the counter substrate of the display device 10. The spacer SP arranged in the array substrate and the spacer SP arranged in the counter substrate face each other to form the cell gap. The spacer SP is arranged at an interval for each of the plurality of pixels.

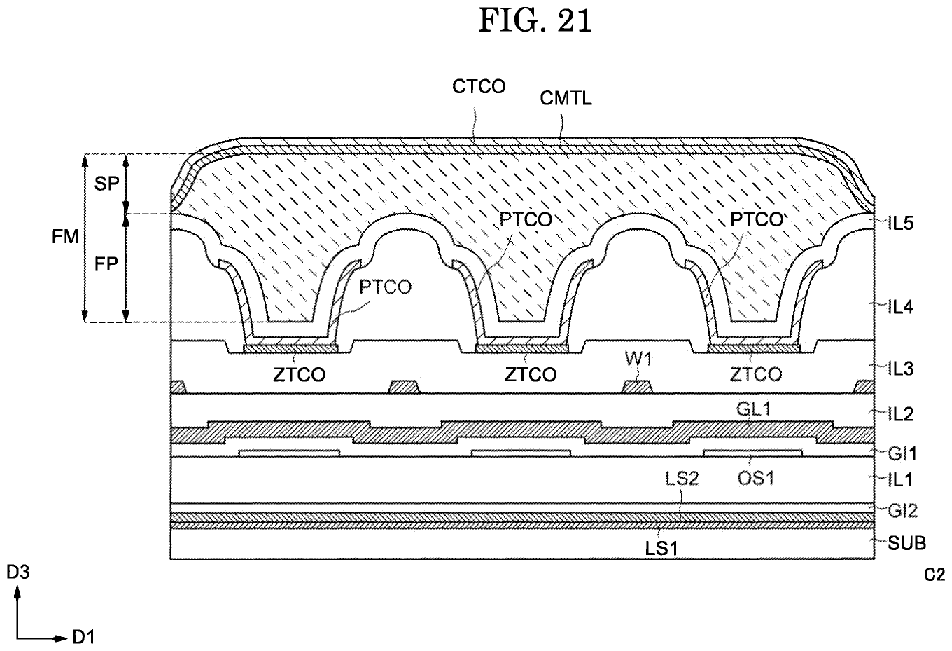

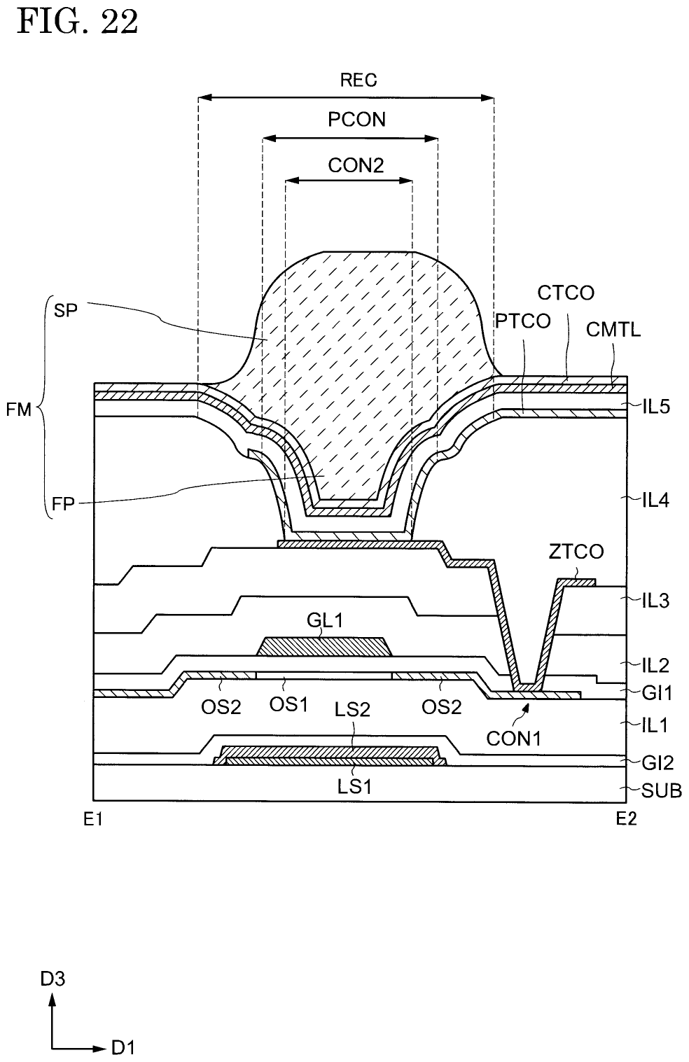

FIG. 20 shows a plan view of the light-shielding layer LS, the common auxiliary electrode CMTL, and the common electrode CTCO. FIG. 21 shows a cross-sectional view cut along a line C1-C2 shown in FIG. 20. FIG. 22 shows a cross-sectional view cut along a line D1-D2 shown in FIG. 20. In FIG. 21 and FIG. 22, since configurations other than the light-shielding layer LS, the common auxiliary electrode CMTL, and the common electrode CTCO are the same as those described in FIG. 9 to FIG. 18, a detailed illustration is omitted.

As shown in FIG. 20, the spacer SP of the filling member FM is arranged above the insulating layer IL5 so as to overlap three recess portions REC and contact holes PCON arranged in the direction D1. The filling part FP of the filling member FM is embedded in the recess portion REC and the contact hole PCON. In an area arranged with the filling member FM, the projecting portion (also referred to as the spacer SP) protruding from the top surface of the pixel electrode PTCO arranged on the insulating layer IL4 is arranged. As shown in FIG. 21 and FIG. 22, the common auxiliary electrode CMTL is arranged above the spacer SP of the filling member FM. In addition, the common electrode CTCO is arranged above the common auxiliary electrode CMTL.

As shown in FIG. 21 and FIG. 22, the region where the spacer SP is arranged is arranged so that the light-shielding layer LS overlaps. As shown in FIG. 20, the common auxiliary electrode CMTL and the common electrode CTCO may have the same pattern as the pixel in which the spacer SP is not arranged.

### 10. Method for Manufacturing Display Device

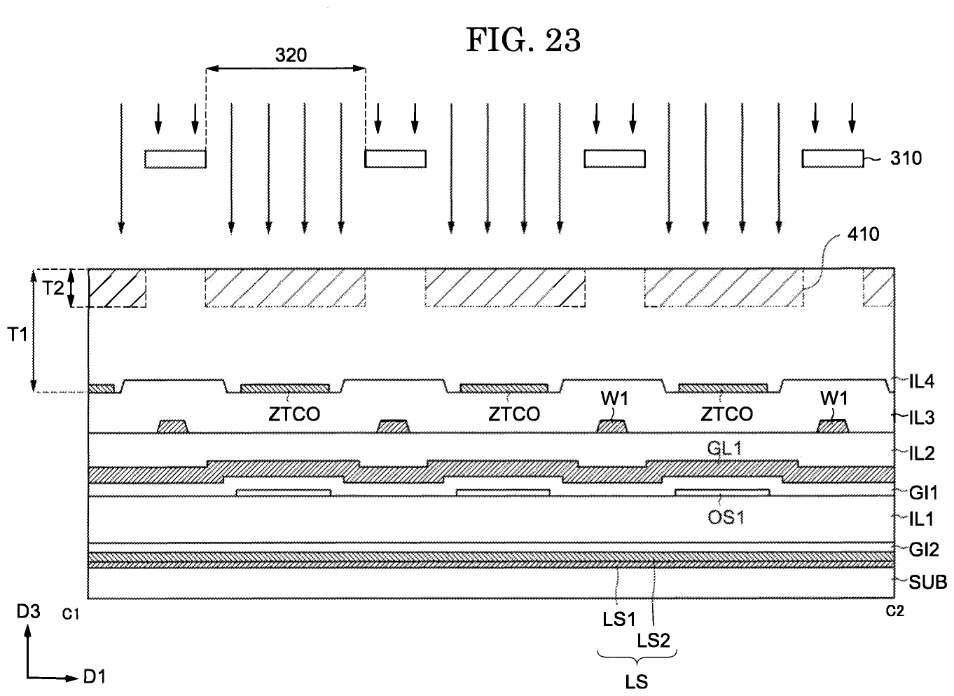

Next, a method for manufacturing the display device 10 according to an embodiment of the present invention will be described with reference to FIG. 23 to FIG. 25. In this case, a method for forming the recess portion REC and the contact hole PCON in the insulating layer IL4 will be described in detail.

FIG. 23 is a diagram showing a step of forming the insulating layer IL4 above the connecting electrode ZTCO and performing a first exposure on the insulating layer IL4. First, as shown in FIG. 23, the insulating layer IL4 is formed above the connecting electrode ZTCO. The thickness T1 of the insulating layer IL4 is, for example, 2.0 μm or more and 4.0 μm or less. In the present embodiment, a positive organic resin is used as the insulating layer IL4. The positive organic resin is softened by irradiation with light (mainly ultraviolet rays).

Next, the insulating layer IL4 is exposed using a mask 310. The mask 310 has an opening 320 having an area larger than the hole diameter of the contact region CON2 to be formed later. When the insulating layer IL4 is irradiated with light via the opening 320 of the mask 310, the insulating layer IL4 having an area corresponding to the opening 320 is exposed. In this case, the intensity of the exposure is constant, and the insulating layer IL4 is exposed for several 100 seconds of exposure time (referred to as integrated exposure). A depth to which the insulating layer IL4 is exposed from the surface is controlled by the exposure time. In the present embodiment, the thickness T2 of 25% or more and 30% or less from the surface of the insulating layer IL4 is exposed with respect to the thickness T1 of the insulating layer IL4. The region where the insulating layer IL4 is exposed is shown as a region 410.

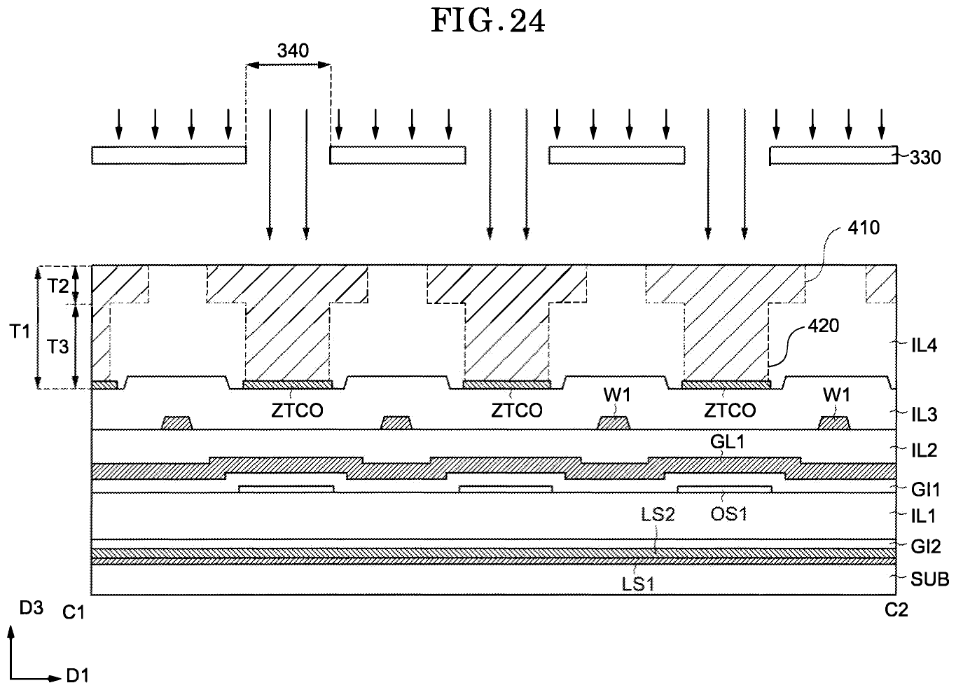

FIG. 24 is a diagram showing a step of switching from the mask 310 to the mask 330 and performing a second exposure on the insulating layer IL4. An area of an opening 340 of the mask 330 is smaller than an area of the opening 320 of the mask 310. The opening 340 of the mask 330 is arranged at a position overlapping the region 410 of the insulating layer IL4. The insulating layer IL4 is already exposed to a depth (the thickness T2) of 25% or more and 30% or less by the first exposure. Therefore, in the second exposure, 70% or more and 75% or less of the remaining thickness T3 of the insulating layer IL4 of the area corresponding to the opening 340 is exposed.

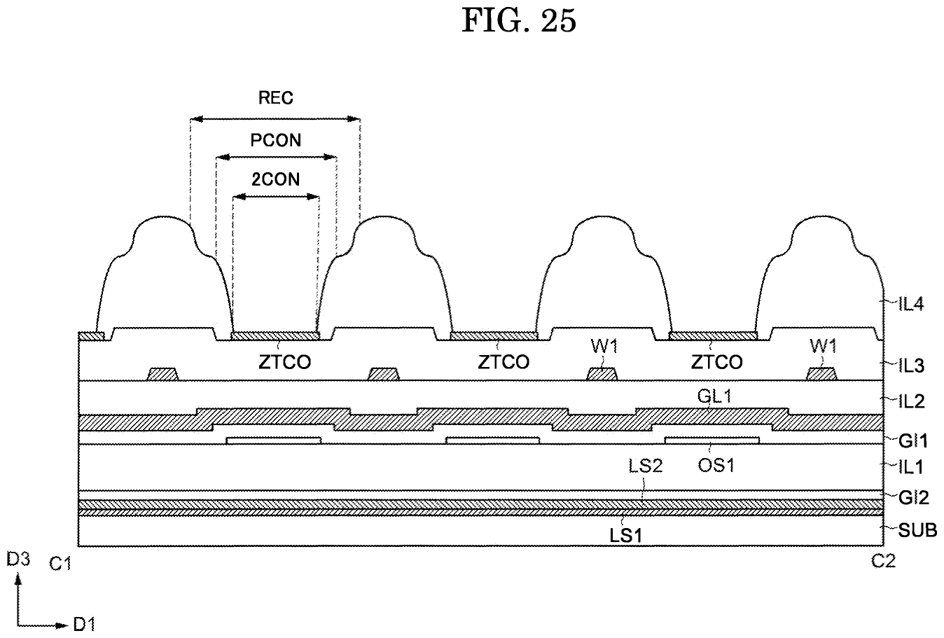

FIG. 25 is a diagram showing a step of developing the insulating layer IL4. The exposed regions 410 and 420 are removed by developing the insulating layer IL4. As a result, the recess portion REC and the contact hole PCON can be formed in the insulating layer IL4. In this case, the region 410 exposed by the first exposure corresponds to the recess portion REC, and the region 420 exposed by the second exposure corresponds to the contact hole PCON. In addition, in the contact hole PCON, the region where the connecting electrode ZTCO is exposed becomes the contact region CON2 that will be connected to the pixel electrode PTCO later.

As described above, the recess portion REC and the contact hole PCON can be formed in the insulating layer IL4. In the case where the exposure is performed on the insulating layer IL4 only by the mask 310 having the wide opening 320, the opening of the contact hole PCON becomes large, and consequently, the display quality of the display device is degraded. In addition, in the case where the exposure is performed on the insulating layer IL4 only by the mask 330 having the narrow opening 340, it is difficult to sufficiently expose the insulating layer IL4 because the thickness T1 of the insulating layer IL4 is large. In the present embodiment, first, the first exposure step is performed on the insulating layer IL4 using the mask 310 having the wide opening 320, and then the second exposure step is performed on the insulating layer IL4 using the mask 330 having the narrow opening 340. Therefore, since the effective thickness of the insulating layer IL4 in the second exposure can be reduced, the hole diameter of the contact hole PCON can be further reduced.

### Second Embodiment

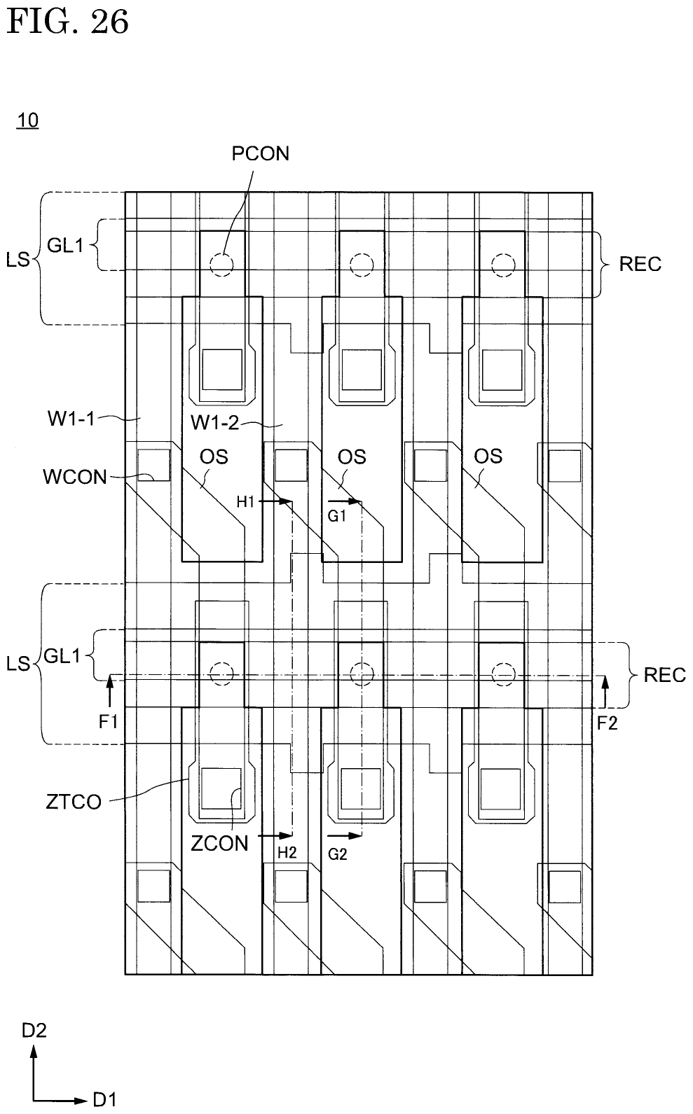

The present embodiment is described with reference to FIG. 26 to FIG. 29 for a display device that differs in some configurations from the display device 10 illustrated in the first embodiment. Specifically, the configurations of the recess portion REC and the contact hole PCON formed in the insulating layer IL4 are different. Therefore, the recess portion REC and the contact hole PCON in the insulating layer IL4 will be described in detail, and other configurations will be omitted as appropriate.

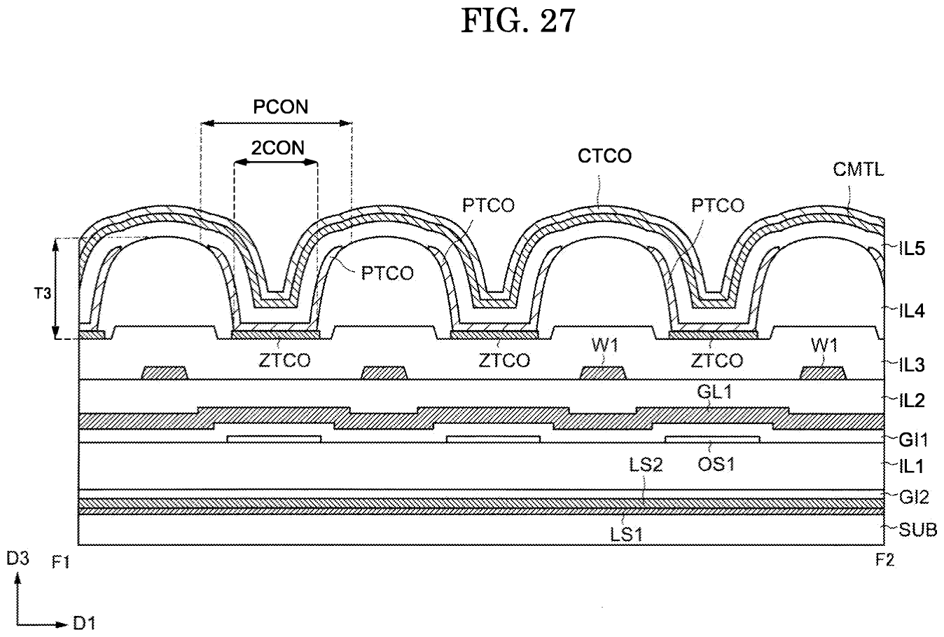

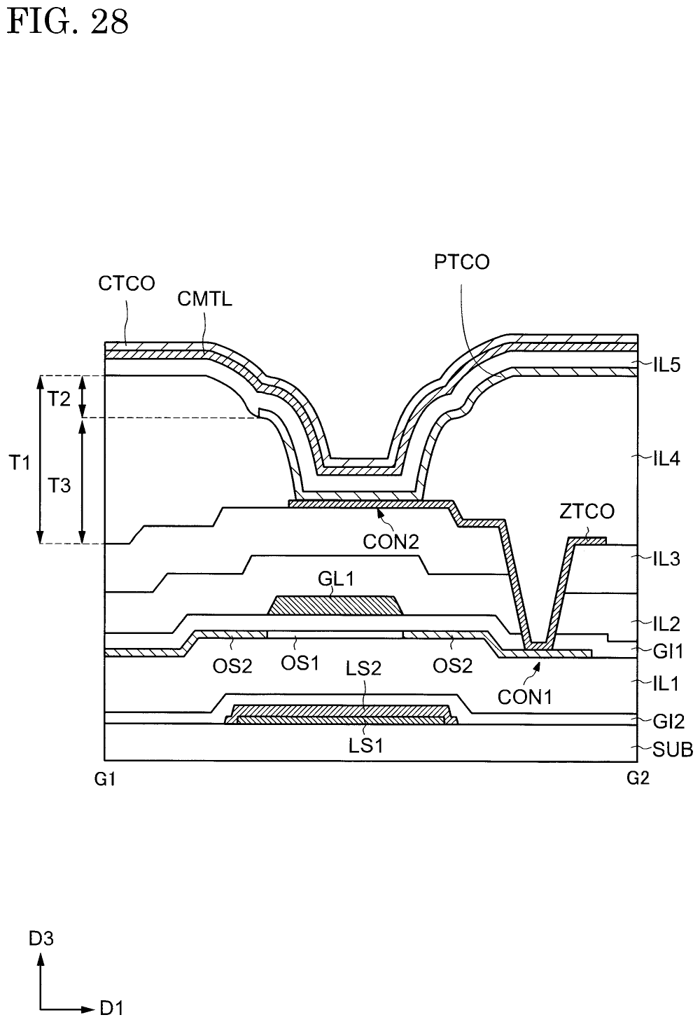

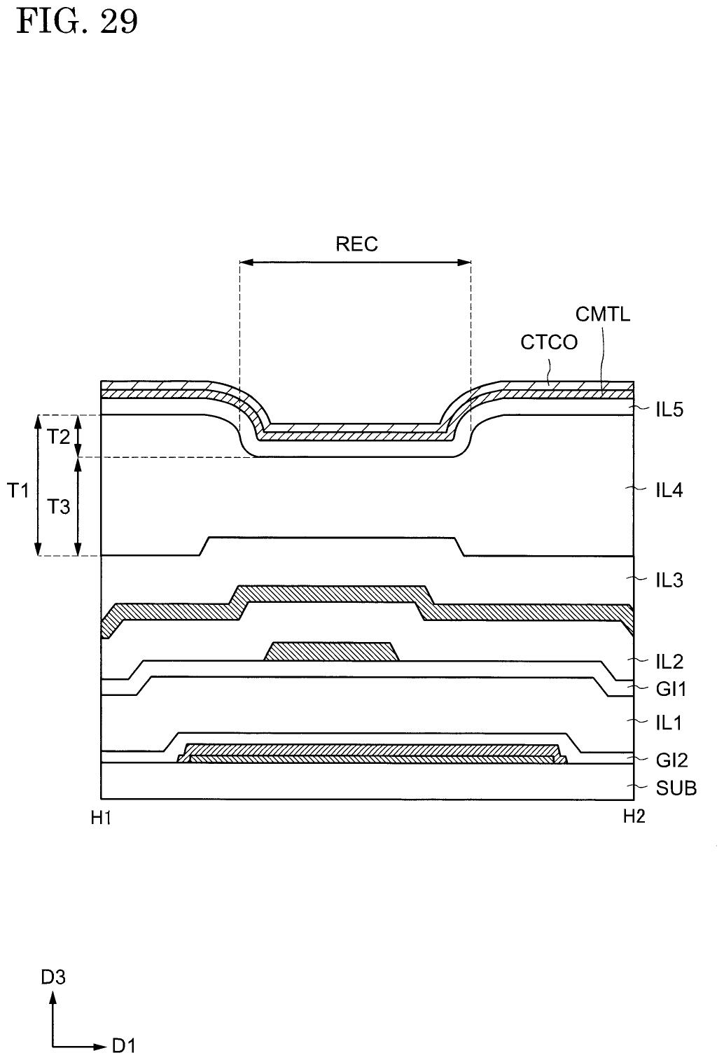

FIG. 26 is a plan view showing a configuration of the display device 10 according to an embodiment of the present invention. FIG. 27 is a cross-sectional view at a line F1-F2 of the display device 10 shown in FIG. 26. FIG. 28 is a cross-sectional view at a line G1-G2 of the display device 10 shown in FIG. 26. FIG. 29 is a cross-sectional view at a line H1-H2 of the display device 10 shown in FIG. 26.

In the present embodiment, the insulating layer IL4 has the recess portion REC extending over the plurality of pixels arranged side by side in the direction D1. In addition, the contact hole PCON is arranged in the region overlapping the connecting electrode ZTCO at the bottom part of the recess portion REC.

The recess portion REC extends along the gate electrode GL1. In addition, the recess portion REC extends along the light-shielding layer LS. In the present embodiment, the recess portion REC may be referred to as a groove because it extends in the direction D1. A length (width) of the recess portion REC in the direction D2 is, for example, 5.0 μm or more and 8.0 μm or less. A width of the recess portion REC may be any width that is hidden by the light-shielding layer LS. In the first embodiment, the minimum dimension between the recess portions REC in adjacent pixels may be restricted by the resolution of the exposure machine. In the present embodiment, forming the recess portion REC so as to extend over the plurality of pixels makes it possible to eliminate the restriction on the resolution of the exposure machine.

As shown in FIG. 26, in a plan view, the interval pitch between the wiring W1-1 and the wiring W1-2 of two pixels adjacent in the direction D1 is preferably 6 μm or more and 7 μm or less. In addition, the hole diameter of the contact hole PCON is preferably 40% or more with respect to the interval pitch between the wiring W1-1 and the wiring W1-2.

As shown in FIG. 27 and FIG. 28, the total thickness of the insulating layer IL4 corresponds to the thickness T1. In addition, in the insulating layer IL4, the depth of the recess portion REC corresponds to the thickness T2 of the insulating layer IL4. Further, the thickness of the insulating layer IL4 to the bottom part of the recess portion REC corresponds to the thickness T3 of the insulating layer IL4. In other words, the depth of the contact hole PCON corresponds to the thickness T3 of the bottom part of the recess portion REC of the insulating layer IL4. The thickness T3 of the insulating layer IL4 to the bottom part of the recess portion REC is 70% or more and 75% or less with respect to the thickness T1 of the insulating layer IL4 where no recess portion REC is arranged.

As shown in FIG. 28, the common auxiliary electrode CMTL arranged over the pixel electrode PTCO and the common electrode CTCO arranged over the common auxiliary electrode CMTL are further arranged, and the recess portion REC overlaps the common auxiliary electrode CMTL.

The arrangement of the spacer SP in the display device 10 in the present embodiment is the same as that in the first embodiment except for the shape of the recess portion REC. That is, it is similar to the layout of the display device 10 shown in FIG. 20 except that the recess portion REC extends in the direction D1. The filling member FM is embedded in the recess portion REC and the contact hole PCON. In an area arranged with the filling member FM, the projecting portion (also referred to as the spacer SP) protruding from the top surface of the pixel electrode PTCO arranged on the insulating layer IL4 is arranged. Similar to the first embodiment, the common auxiliary electrode CMTL is arranged above the spacer SP of the filling member FM. In addition, the common electrode CTCO is arranged above the common auxiliary electrode CMTL.

In the display device according to the present embodiment as well, arranging the contact hole PCON for each pixel at the bottom part of the recess portion REC extending in the direction D1 arranged in the insulating layer IL4 makes it possible to reduce the hole diameter of the contact hole PCON without unnecessarily reducing the thickness T1. In addition, the angle of the side wall of the contact hole PCON can be increased. As a result, it is possible to suppress the distance L1 between the wiring W1 and the pixel electrode PTCO covering the side wall of the contact hole PCON from being reduced in the direction D1. As a result, it is possible to suppress the formation of the parasitic capacitance by the wiring W1 and the pixel electrode PTCO on the side surface of the contact hole PCON. Therefore, even when the pixel is driven at high speed, it is possible to suppress an increase in the load between the wiring W1 and the pixel electrode PTCO. Therefore, the power consumption of the display device can be reduced.

In addition, since the thickness T1 of the insulating layer IL4 can be sufficiently increased, it is possible to suppress the distance L2 between the wiring W1 and the common electrode CTCO from being reduced. As a result, it is possible to suppress the formation of the parasitic capacitance by the wiring W1 and the common electrode CTCO. Therefore, even when the pixel is driven at high speed, capacitive coupling caused by the parasitic capacitance can suppress the fluctuation in the potential of the pixel electrode PTCO due to the potential of the wiring W1. Therefore, it is possible to suppress the occurrence of crosstalk in the display device.

### 11. Materials of Each Member of Display Device

A rigid substrate having light transmittance and having no flexibility, such as a glass substrate, a quartz substrate, or a sapphire substrate, can be used as the substrate SUB. On the other hand, in the case where the substrate SUB needs to have flexibility, a flexible substrate containing a resin and having flexibility, such as a polyimide substrate, an acrylic substrate, a siloxane substrate, or a fluororesin substrate, can be used as the substrate SUB. In order to improve the heat resistance of the substrate SUB, impurities may be introduced into the resin.

Metal materials can be used as the gate electrodes GL1 and GL2, the wirings W1 and W2, the light-shielding layer LS, and the common auxiliary electrode CMTL. For example, aluminum (A1), titanium (Ti), chromium (Cr), cobalt (Co), nickel (Ni), molybdenum (Mo), hafnium (Hf), tantalum (Ta), tungsten (W), bismuth (Bi), or silver (Ag), or an alloy or compound thereof is used as the metal material. The above-described metal material may be used in a single layer or in a stacked layer as a member of the electrode or the like.

For example, a stacked structure of Ti layer, A1 layer, and Ti layer is used as the gate electrode GL1. In the present embodiment, the cross-sectional shape of a pattern end of the gate electrode GL1 having the stacked structure is a forward tapered shape.

Common insulating materials can be used as the gate insulating layers GI1 and GI2 and the insulating layers IL1 to IL5. For example, inorganic insulating layers, such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ), can be used as the insulating layers IL1 to IL3, and IL5. An insulating layer with few defects can be used as these insulating layers. An organic insulating material such as a polyimide resin, an acryl resin, an epoxy resin, a silicone resin, a fluororesin, or a siloxane resin can be used as the insulating layer IL4. The above-described organic insulating materials may be used as the gate insulating layers GI1 and GI2 and the insulating layers IL1 to IL3, and IL5. The above-described insulating material may be used in a single layer or in a stacked layer as the member of the insulating layer or the like.

The above-described SiOₓN_{y} and AlOₓN_{y} are a silicon compound and an aluminum compound containing a smaller proportion (x>y) of nitrogen (N) than oxygen (O). SiNₓO_{y} and AlNₓO_{y} are a silicon compound and an aluminum compound containing a smaller proportion (x>y) of oxygen than nitrogen.

An example of the insulating layer includes SiOₓ with a thickness of 100 nm used as the gate insulating layer G11. A stacked structure of SiOₓ, SiNₓ, and SiOₓ with a total thickness of 600 nm to 700 nm is used as the insulating layer IL1. A stacked structure of SiOₓ and SiNₓ with a total thickness of 60 nm to 100 nm is used as the gate insulating layer GI2. A stacked structure of SiOₓ, SiNₓ, and SiOₓ with a total thickness of 300 nm to 500 nm is used as the insulating layer IL2. SiOₓ (single layer), SiNₓ (single layer), or a stack thereof with a total thickness of 200 nm to 500 nm is used as the insulating layer IL3. An organic insulating material with the thickness T1 of 2.0 μm to 4.0 μm is used as the insulating layer IL4. SiNₓ (single layer) with a thickness of 50 nm to 150 nm is used as the insulating layer IL5.

An organic insulating material, such as a polyimide resin, an acryl resin, an epoxy resin, a silicone resin, a fluororesin, or a siloxane resin, is used as the filling member FM.

An oxide semiconductor having semiconductor characteristics can be used as the oxide semiconductor layer OS. The oxide semiconductor layer OS has light transmittance. For example, an oxide semiconductor containing two or more metals including indium (In) is used as the oxide semiconductor layer OS. For example, an oxide semiconductor containing indium (In), gallium (Ga), zinc (Zn), and oxygen (O) may be used as the oxide semiconductor layer OS. In particular, an oxide semiconductor having a composition ratio of In:Ga:Zn:0=1:1:1:4 may be used. However, the compositions of the oxide semiconductor layer OS used in the present embodiment are not limited to the above, and an oxide semiconductor having a composition other than those described above can also be used. For example, the ratio of In may be larger than the above described ratio in order to improve the mobility. In addition, the ratio of Ga may be larger than the above described ratio in order to increase the bandgap and reduce the effect of light irradiation. The oxide semiconductor layer OS may be amorphous or polycrystalline. The oxide semiconductor layer OS may be a mixed phase of amorphous and crystalline.

In addition, the ratio of indium to the entire oxide semiconductor layer OS may be 50% or more as the oxide semiconductor layer OS. In addition to indium, gallium (Ga), zinc (Zn), aluminum (Al), hafnium (Hf), yttrium (Y), zirconium (Zr), and lanthanoids are used as the oxide semiconductor layer OS. Elements other than those described above may be used as the oxide semiconductor layer OS. In the case where the ratio of indium relative to the total of the oxide semiconductor layer OS is 50% or more, the oxide semiconductor layer OS has a polycrystalline structure.

A transparent conductive layer is used as the connecting electrode ZTCO, the pixel electrode PTCO, and the common electrode CTCO. A mixture of indium oxide and tin oxide (ITO) or a mixture of indium oxide and zinc oxide (IZO) can be used as the transparent conductive layer. A material other than the above may be used as the transparent conductive layer.

Each of the embodiments described above as an embodiment of the present invention can be appropriately combined and implemented as long as no contradiction is caused. Further, the addition, deletion, or design change of components, or the addition, deletion, or condition change of process as appropriate by those skilled in the art based on the display device of each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A display device comprising a plurality of pixels arranged in a matrix on a substrate along a first direction and a second direction intersecting the first direction,
each of the plurality of pixels comprises:
a transistor;
a first wiring arranged over the transistor and electrically connected to the transistor;
a first transparent conductive layer arranged over the first wiring and electrically connected to the transistor;
a first insulating layer arranged on the first transparent conductive layer, and having a contact hole; and
a second transparent conductive layer arranged on the first insulating layer and electrically connected to the first transparent conductive layer via the contact hole,
wherein the first insulating layer has a recess portion overlapping the first transparent conductive layer,
the recess portion is continuous with the contact hole, and
the contact hole is arranged at a bottom part of the recess portion.

2. The display device according to claim 1, wherein an interval between the first wirings of two pixels adjacent to each other in the second direction is 4 μm or more and 8 μm or less, and a contact area between the first transparent conductive layer and the second transparent conductive layer is 40% or more of the interval between the first wirings.

3. The display device according to claim 1, wherein a thickness of the first insulating layer in the recess portion is 70% or more and 75% or less with respect to the thickness of the first insulating layer without the recess portion.

4. The display device according to claim 1, further comprising:
a common auxiliary electrode arranged over the second transparent conductive layer; and
a third transparent conductive layer arranged over the common auxiliary electrode,
wherein the recess portion overlaps the common auxiliary electrode.

5. The display device according to claim 4, further comprising:
a filling member filled in the contact hole,
wherein the filling member has a projecting portion protruding above a top surface of the third transparent conductive layer.

6. A display device comprising a plurality of pixels arranged in a matrix on a substrate along a first direction and a second direction intersecting the first direction,
each of the plurality of pixels comprises:
a transistor;
a first wiring arranged over the transistor and electrically connected to the transistor;
a first transparent conductive layer arranged over the first wiring and electrically connected to the transistor;
a first insulating layer arranged on the first transparent conductive layer, and having a contact hole; and
a second transparent conductive layer arranged on the first insulating layer and electrically connected to the first transparent conductive layer via the contact hole,
wherein the first insulating layer has a recess portion extending over a plurality of pixels arranged side-by-side in the second direction,
the recess portion is arranged continuously with the contact hole, and
the contact hole is arranged at a bottom part of the recess portion overlapping the first transparent conductive layer.

7. The display device according to claim 6, wherein an interval of the first wirings of two pixels adjacent to each other in the second direction is 4 μm or more and 8 μm or less, and a contact area between the first transparent conductive layer and the second transparent conductive layer is 40% or more of the interval between the first wirings.

8. The display device according to claim 6, wherein a thickness of the first insulating layer in the recess portion is 70% or more and 75% or less of the thickness of the first insulating layer without the recess portion.

9. The display device according to claim 6, further comprising:
a common auxiliary electrode arranged over the second transparent conductive layer; and
a third transparent conductive layer arranged over the common auxiliary electrode,
wherein the recess portion overlaps the common auxiliary electrode.

10. The display device according to claim 9, further comprising a filling member filled in the contact hole,
wherein the filling member has a projecting portion protruding above a top surface of the third transparent conductive layer.

11. A display device comprising:
a substrate;
a pixel arranged on the substrate, and having a transistor, a pixel electrode, and a common electrode;
a wiring connected to a first electrode of the transistor;
a conductive layer connected to a second electrode of the transistor;
an insulating layer arranged over the conductive layer, and having a contact hole;
wherein the pixel electrode is connected to the conductive layer via the contact hole,
the contact hole includes a first region having a first side surface and a second region having a second side surface and located between the first region and the conductive layer,
a bottom part of the first region is continuous with a top of the second region,
a tangent line of the first side surface at a bottom of the first region makes a first angle with a main surface of the substrate,
a tangent line of the second side surface at a bottom of the second region makes a second angle with the main surface of the substrate,
the first angle is less than the second angle, and
a portion of the insulating layer is located between the wiring and the common electrode.

12. The display device according to claim 11, wherein
the wiring does not overlap the contact hole in a plan view.

13. The display device according to claim 11, wherein
the wiring overlaps the common electrode in a plan view.

14. The display device according to claim 11, wherein
the pixel electrode is in contact with the entire second region.

15. The display device according to claim 14, wherein
the pixel electrode is in contact with a first portion of the first region and not in contact with a second portion of the first region.

16. The display device according to claim 11, wherein
a gate electrode of the transistor overlaps the contact hole.

17. The display device according to claim 11, further comprising:
a light-shielding layer located between the substrate and the transistor,
wherein the light-shielding layer overlaps the contact hole in a plan view.

18. The display device according to claim 17, wherein
the light-shielding layer does not overlap a region where the second electrode and the conductive layer are connected in a plan view.
